(19) United States
(12) Patent Application Publication
(10) Pub. No.: US 2010/0327361 A1
(43) Pub. Date: Dec. 30, 2010

(54) LOW COST SYMMETRIC TRANSISTORS

(76) Inventors: KAMEL BENAISSA, Dallas, TX (US); Greg C. Baldwin, Plano, TX (US); Shaofeng Yu, Plano, TX (US)

Correspondence Address: TEXAS INSTRUMENTS INCORPORATED, P O BOX 655474, M/S 3999, DALLAS, TX, 75265, US

(21) Appl. No.: 12/492,818

(22) Filed: Jun. 26, 2009

(51) Int. Cl. H01L 29/78; H01L 21/336

(52) U.S. Cl. 257/368; 438/302; 257/E29.266; 257/E21.437

(57) ABSTRACT

An integrated circuit is disclosed containing two types of MOS transistors of the same polarity, oriented perpendicularly to each other, formed by concurrent halo ion, LDD ion and/or S/D ion implant processes using angled, rotated sub-implants which vary the tilt angle, dose and/or energy between rotations. Implanted halo, LDD and/or S/D source and drain regions formed by angled subimplants may have different extents of overlap with, or lateral separation from, gates of the two types of transistors, producing transistors with two different sets of electrical properties. A process for concurrently fabricating the two types of transistors is also disclosed.

### CROSS-REFERENCE TO RELATED APPLICATIONS

The following co-pending application is related and hereby incorporated by reference: U.S. patent application Ser. No. ______, filed ______ (TI-66483), entitled LOW COST TRANSISTORS USING GATE ORIENTATION AND OPTIMAIZED IMPLANTS.

### FIELD OF THE INVENTION

This invention relates to the field of integrated circuits. More particularly, this invention relates to MOS transistors in integrated circuits.

### BACKGROUND OF THE INVENTION

Integrated circuits frequently contain several types of metal oxide semiconductor (MOS) transistors, each type having certain electrical properties. MOS transistors are fabricated using ion implantation processes to form n-type and p-type ion implanted regions in the MOS transistors, including halo regions, lightly doped drain (LDD) regions or medium doped drain (MDD) regions, and source/drain (S/D) regions. Details of spatial configurations of ion implanted regions, such as lateral extents of overlap or separation between the ion implanted regions and gates of the MOS transistors, affect the electrical properties of the MOS transistors. Other physical properties of the ion implanted regions, including doping densities and dopant species, also affect the electrical properties of the MOS transistors. MOS transistors designed to have different electrical properties frequently have different spatial configurations of ion implanted regions, and may also have different doping densities and different distributions of dopant species.

Ion implanted regions are typically formed using photoresist patterns which expose areas on integrated circuits to be implanted. The photoresist patterns are removed during subsequent processing. Forming and removing photoresist patterns undesirably increases fabrication cost and complexity of integrated circuits.

### SUMMARY OF THE INVENTION

The instant invention provides an integrated circuit containing two types of MOS transistors of the same polarity, that is both types of MOS transistors are NMOS or both types of MOS transistors are PMOS. Longitudinal axes of gates of the first type of MOS transistors are all parallel to each other. Longitudinal axes of the second type of MOS transistors are all parallel to each other, and are perpendicular to the longitudinal axes of the gates of the first type of MOS transistors. Concurrent halo ion implant processes, LDD ion implant processes and/or S/D ion implant processes are performed using angled, rotated sub-implants which vary the tilt angle, dose and/or energy between rotations. Implanted halo, LDD and/or S/D source and drain regions formed by angled subimplants may have different extents of overlap with, or lateral separation from, gates of the two types of transistors. Thus, transistors with two different sets of electrical properties may be formed concurrently using a common set photoresist patterns and ion implant processes, advantageously reducing fabrication cost and complexity of the integrated circuit.

### DESCRIPTION OF THE VIEWS OF THE DRAWING

FIG. 1A through FIG. 1C depict an integrated circuit having two types of transistors, formed according to the instant invention.

FIG. 2 is a top view of an alternate embodiment of the instant invention, depicted during an ion implantation process.

FIG. 3A through FIG. 3C depict an integrated circuit having a first transistor and a second transistor formed according to a first specific embodiment of the instant invention.

FIG. 4A through FIG. 4C depict an integrated circuit having a first transistor and a second transistor, possibly a drain extended MOS (DMOS) transistor, formed according to a second specific embodiment of the instant invention.

FIG. 5A through FIG. 5C depict an integrated circuit having a first transistor and a second transistor formed according to a third specific embodiment of the instant invention.

FIG. 6A through FIG. 6C depict an integrated circuit having a first transistor and a second transistor formed according to a fourth specific embodiment of the instant invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

An integrated circuit may be conceptualized as a rectangular solid in which MOS transistors and other components are formed on a top surface of the rectangular solid. Typically, lateral dimensions of the top surface are greater than a thickness of the rectangular solid, the thickness being a length of a dimension of the rectangular solid perpendicular to the top surface. Furthermore, an integrated circuit may be assigned a preferred orientation, based on a layout of components in the integrated circuit or other consideration, so that one edge of the top surface of the integrated circuit may be identified as an upper edge, and an opposite edge of the upper surface may be identified as a lower edge, such that the lower edge is parallel to the upper edge. A right edge is that edge of the top surface which is perpendicular to the upper edge and the lower edge, and which connects to a right-hand end of the upper edge and to a right-hand end of the lower edge. Correspondingly, a left edge is that edge of the top surface which is perpendicular to the upper edge and the lower edge, is opposite the right edge, and which connects to a left-hand end of the upper edge and to a left-hand end of the lower edge. Proceeding in a clockwise direction around a perimeter of the top surface, starting with the upper edge, one encounters the right edge, subsequently the lower edge and finally the left edge. For the purposes of this disclosure, the term “upper direction” is understood to mean a direction in the top surface toward the upper edge. Similarly, for the purposes of this disclosure, the term “upper side” of an element is understood to mean a lateral side of the element facing the upper edge or closer to the upper edge than other lateral sides of the element. For the purposes of this disclosure, the term “right direction” is understood to mean a direction in the top surface toward the right edge. Similarly, for the purposes of this disclosure, the term “right side” of an element is understood to mean a lateral side of the element facing the right edge or closer to the right edge than other lateral sides of the element. For the purposes of this disclosure, the term “lower direction” is understood to mean a direction in the top surface toward the lower edge. Similarly, for the purposes of this disclosure, the term “lower side” of an element is understood to mean a lateral side of the element facing the lower edge or closer to the lower edge than other lateral sides of the element. For the purposes of this disclosure, the term “left direction” is understood to mean a direction in the top surface toward the left edge. Similarly, for the purposes of this disclosure, the term “left side” of an element is understood to mean a lateral side of the element facing the left edge or closer to the left edge than other lateral sides of the element.

An MOS transistor on a top surface of an integrated circuit includes a gate, a source region adjacent to one side of the gate, and a drain region adjacent to the gate opposite the source region. Charged carriers flow in the MOS transistor from the source region under the gate to the drain region. A longitudinal axis of the gate is identified as an axis in the gate, parallel to the top surface of the integrated circuit, perpendicular to the direction of charged carrier flow. For example, an MOS transistor in which charged carriers flow in the upper direction has a gate with a left-right longitudinal axis. Similarly, an MOS transistor in which charged carriers flow in the left direction has a gate with an upper-lower longitudinal axis.

To assist reading of this disclosure, source/drain extensions commonly known as lightly doped drain (LDD) and medium doped drain (MDD) regions will collectively be referred to as LDD regions.

The instant invention provides an integrated circuit containing two types of MOS transistors of a same polarity, that is both types of MOS transistors are NMOS or both types of MOS transistors are PMOS. Longitudinal axes of gates of a first type of MOS transistors are all parallel to each other. Longitudinal axes of a second type of MOS transistors are all parallel to each other, and are perpendicular to the longitudinal axes of the gates of the first type of MOS transistors. Both types of MOS transistors are formed using halo ion implant processes, LDD ion implant processes and S/D ion implant processes. Each ion implant process forms an ion implanted layer at a top surface of the integrated circuit. Ion implanted regions in each transistor include the ion implanted layer, bounded by gates of the transistor and field oxide or other isolation structure. Halo implanted regions of the first type of MOS transistors and of the second type of MOS transistors, and/or LDD implanted regions of the first type of MOS transistors and of the second type of MOS transistors, and/or source drain (S/D) implanted regions of the first type of MOS transistors and of the second type of MOS transistors are formed using common photoresist patterns and ion implant processes which are divided into one or more angled sub-implants. Each sub-implant may be angled from a perpendicular axis to a top surface of the integrated circuit toward a different direction in the integrated circuit. For example, a halo implant may be performed in four sub-implants, with a first sub-implant angled toward the upper direction, a second sub-implant angled toward the right direction, a third sub-implant angled toward the lower direction, and a fourth sub-implant angled toward the left direction. In another example, an LDD implant may be performed in two sub-implants, with a first sub-implant angled toward the upper direction, and a second sub-implant angled toward the lower direction. In a further example, an S/D implant may be performed in one sub-implant angled toward the left direction. Implanted halo, LDD and S/D regions formed by angled subimplants according to the instant invention have different extents of overlap with, or lateral separation from, gates of the two types of transistors. Thus, transistors with two different sets of electrical properties may be formed concurrently using a common set photoresist patterns and ion implant processes, advantageously reducing fabrication cost and complexity of the integrated circuit. Halo ion implanted regions are p-type in NMOS transistors, and are n-type in PMOS transistors. LDD ion implanted regions are n-type in NMOS transistors, and are p-type in PMOS transistors. S/D ion implanted regions are n-type in NMOS transistors, and are p-type in PMOS transistors.

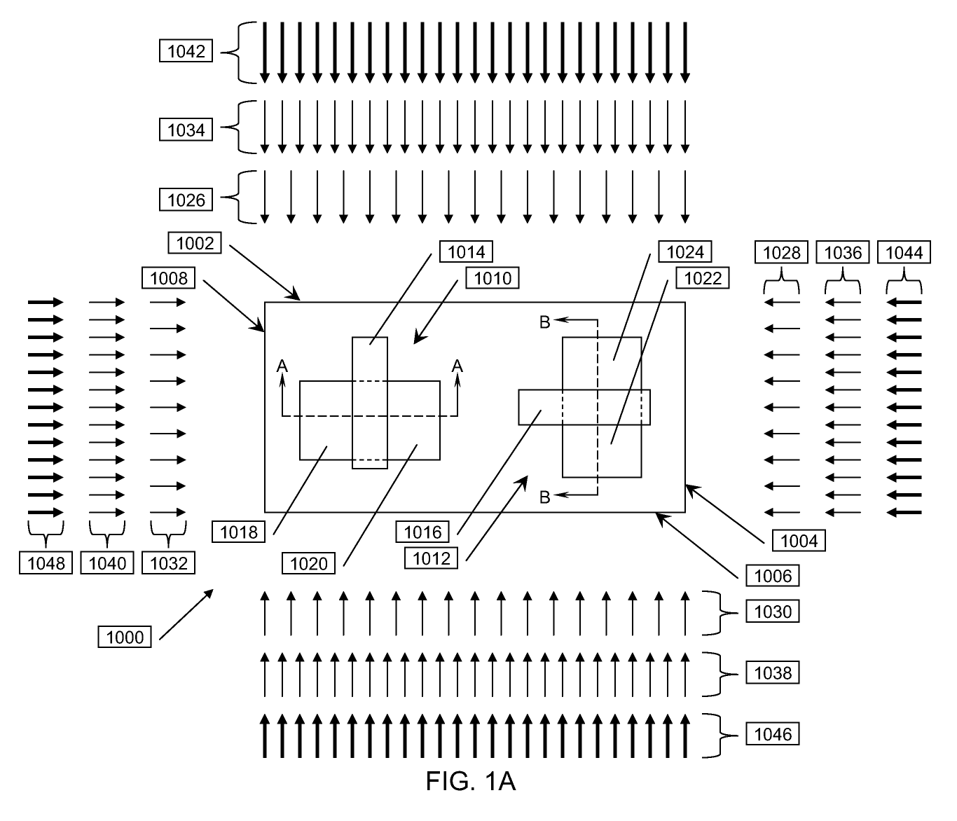

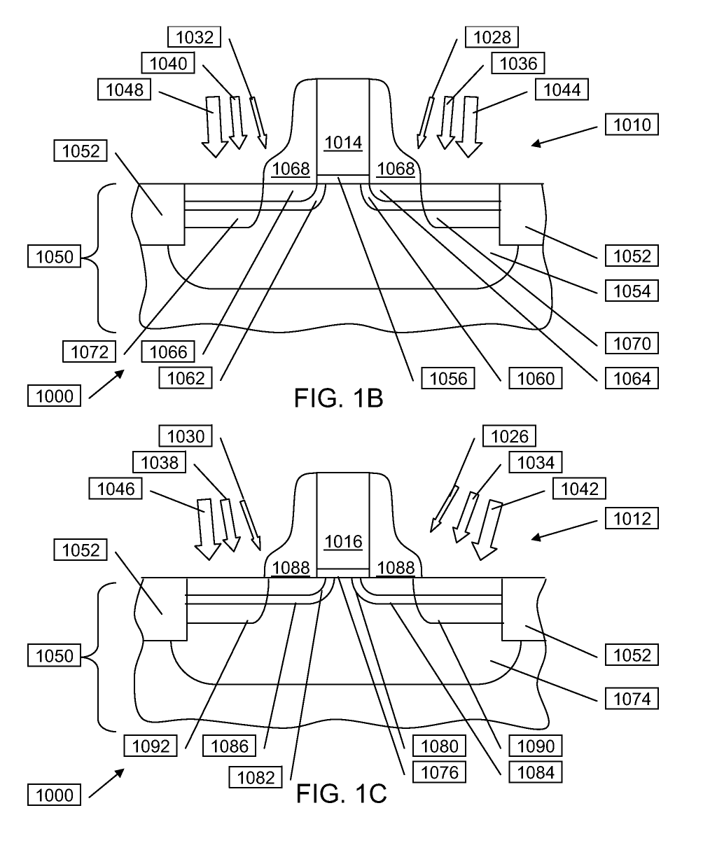

FIG. 1A through FIG. 1C depict an integrated circuit containing two types of transistors, formed according to the instant invention. Referring to FIG. 1A, the integrated circuit (1000) has an upper edge (1002), a right edge (1004), a lower edge (1006) and a left edge (1008). The integrated circuit contains a first type of MOS transistor (1010) and a second type of MOS transistor (1012). The first type of MOS transistor (1010) has a first gate (1014) with an upper-lower longitudinal axis. The second type of MOS transistor (1012) has a second gate (1016) with a left-right longitudinal axis. Offset and sidewall spacers commonly formed on lateral surfaces of MOS gates are not shown in FIG. 1A for clarity. The first type of MOS transistor (1010) includes a first source area (1018) adjacent to the first gate (1014), and a first drain area (1020) adjacent to the first gate (1014) opposite the first source area (1018). The second type of MOS transistor (1012) includes a second source area (1022) adjacent to the second gate (1016), and a second drain area (1024) adjacent to the second gate (1016) opposite the second source area (1022). Other components in the integrated circuit (1000) are not shown in FIG. 1A for clarity.

The first type of MOS transistor (1010) and the second type of MOS transistor (1012) are formed using halo, LDD and S/D ion implant processes which produce halo, LDD and S/D ion implanted layers at a top surface of the integrated circuit (1000). In one embodiment, the first type of MOS transistor (1010) and the second type of MOS transistor (1012) are formed using angled halo sub-implants, depicted in FIG. 1A as a first halo sub-implant (1026) angled toward the upper direction, a second halo sub-implant (1028) angled toward the right direction, a third halo sub-implant (1030) angled toward the lower direction, and a fourth halo sub-implant (1032) angled toward the left direction. At least one of a tilt angle, dose, energy or dopant species may be different between the first halo sub-implant (1026), the second halo sub-implant (1028), the third halo sub-implant (1030) and the fourth halo sub-implant (1032). In further embodiments, one, two or three of the first halo sub-implant (1026), the second halo sub-implant (1028), the third halo sub-implant (1030) and the fourth halo sub-implant (1032) may be omitted during formation of the first type of MOS transistor (1010) and the second type of MOS transistor (1012). For illustrative purposes, the first halo sub-implant (1026) is depicted in FIG. 1A as having a larger tilt angle from a perpendicular axis to the top surface of the integrated circuit (1000) than the third halo sub-implant (1030), and the third halo sub-implant (1030) is depicted as having a larger tilt angle from the perpendicular axis than the second halo sub-implant (1028) and the fourth halo sub-implant (1032).

In another embodiment, the first type of MOS transistor (1010) and the second type of MOS transistor (1012) are formed using angled LDD sub-implants, depicted in FIG. 1A as a first LDD sub-implant (1034) angled toward the upper direction, a second LDD sub-implant (1036) angled toward the right direction, a third LDD sub-implant (1038) angled toward the lower direction, and a fourth LDD sub-implant (1040) angled toward the left direction. At least one of a tilt angle, dose, energy or dopant species may be different between the first LDD sub-implant (1034), the second LDD sub-implant (1036), the third LDD sub-implant (1038) and the fourth LDD sub-implant (1040). In further embodiments, one, two or even three of the first LDD sub-implant (1034), the second LDD sub-implant (1036), the third LDD sub-implant (1038) and the fourth LDD sub-implant (1040) may be omitted during formation of the first type of MOS transistor (1010) and the second type of MOS transistor (1012). For illustrative purposes, the first LDD sub-implant (1034) is depicted as having a higher tilt angle from the perpendicular axis than the third LDD sub-implant (1038), and the third LDD sub-implant (1038) is depicted as having a larger tilt angle from the perpendicular axis than the second LDD sub-implant (1036) and the fourth LDD sub-implant (1040).

In a further embodiment, the first type of MOS transistor (1010) and the second type of MOS transistor (1012) are formed using angled S/D sub-implants, depicted in FIG. 1A as a first S/D sub-implant (1042) angled toward the upper direction, a second S/D sub-implant (1044) angled toward the right direction, a third S/D sub-implant (1046) angled toward the lower direction, and a fourth S/D sub-implant (1048) angled toward the left direction. At least one of a tilt angle, dose, energy or dopant species may be different between the first S/D sub-implant (1042), the second S/D sub-implant (1044), the third S/D sub-implant (1046) and the fourth S/D sub-implant (1048). In further embodiments, one, two or even three of the first S/D sub-implant (1042), the second S/D sub-implant (1044), the third S/D sub-implant (1046) and the fourth S/D sub-implant (1048) may be omitted during formation of the first type of MOS transistor (1010) and the second type of MOS transistor (1012). For illustrative purposes, the first S/D sub-implant (1042) is depicted as having a higher tilt angle from the perpendicular axis than the third S/D sub-implant (1046), and the third S/D sub-implant (1046) is depicted as having a larger tilt angle from the perpendicular axis than the second S/D sub-implant (1044) and the fourth S/D sub-implant (1048).

FIG. 1B and FIG. 1C are cross-sections of the integrated circuit (1000), through the first type of MOS transistor (1010) and the second type of MOS transistor (1012) depicted in FIG. 1A. FIG. 1B depicts a cross-section at section line A-A of FIG. 1A. FIG. 1C depicts a cross-section at section line B-B of FIG. 1A. Referring to FIG. 1B, the first type of MOS transistor (1010) is formed on a substrate (1050) of the integrated circuit (1000), which is commonly a single crystal silicon wafer, but may be a silicon-on-insulator (SOI) wafer, a hybrid orientation technology (HOT) wafer with regions of different crystal orientations, or other material appropriate for fabrication of the IC (1000). Elements of field oxide (1052) may be formed at a top surface of the substrate (1050), typically of silicon dioxide between 250 and 600 nanometers thick, commonly by shallow trench isolation (STI) or local oxidation of silicon (LOCOS) processes. In STI processes, silicon dioxide may be deposited by high density plasma (HDP) or high aspect ratio process (HARP). A first well (1054) may be formed in the substrate (1050), typically by ion implanting a set of dopants at doses between 1·10¹¹ to 1·10¹⁴ atoms/cm², into a region defined for the first type of MOS transistor (1010). The first type of MOS transistor (1010) includes a first gate dielectric layer (1056), formed on a top surface of the substrate (1050). The first gate dielectric layer (1056) is typically silicon dioxide, nitrogen doped silicon dioxide, silicon oxy-nitride, hafnium oxide, layers of silicon dioxide and silicon nitride, or other insulating material, and commonly between 1 and 5 nanometers thick. The first gate dielectric layer (1056) is typically formed using any of a variety of gate dielectric formation process, for example thermal oxidation, plasma nitridation of an oxide layer, and/or dielectric material deposition by atomic layer deposition (ALD) processes. The first MOS gate (1014) is formed on a top surface of the first gate dielectric layer (1056), typically of polycrystalline silicon, commonly known as polysilicon, between 50 and 150 nanometers thick. A lateral length of the first MOS gate (1014), in the direction of charged carrier flow, is selected to provide a desired on-state current density of the first type of MOS transistor (1010).

A first drain side halo implanted region (1060) is formed by the first halo sub-implant, not shown in FIG. 1B for clarity, the second halo sub-implant (1028), the third halo sub-implant, not shown in FIG. 1B for clarity, and the fourth halo sub-implant (1032). A lateral extent of an overlap or separation between the first MOS gate (1014) and a left edge of the first drain side halo implanted region (1060) is established by a halo sub-implant which places halo dopants the farthest under, or closest to, the first MOS gate (1014). The second halo sub-implant (1028), if performed, establishes a larger lateral extent of the overlap between the first MOS gate (1014) and the first drain side halo implanted region (1060) compared to the other three halo sub-implants, because the second halo sub-implant (1028) has the largest angle from the perpendicular axis toward the right direction, and thus implants halo dopants a certain distance under the first MOS gate (1014). A larger angle of the second halo sub-implant (1028) from the perpendicular axis produces a larger lateral extent of the overlap between the first MOS gate (1014) and the first drain side halo implanted region (1060). If the second halo sub-implant (1028) is not performed, the first halo sub-implant, not shown in FIG. 1B for clarity, if performed, and/or the third halo sub-implant, not shown in FIG. 1B for clarity, if performed, establish the left edge of the first drain side halo implanted region (1060) to be substantially aligned with the lateral surface of the first MOS gate (1014) facing the right edge of the integrated circuit (1000), because the first halo sub-implant and the third halo sub-implant are substantially parallel to a lateral surface of the first MOS gate (1014) facing the right edge of the integrated circuit (1000). If none of the second halo sub-implant (1028), the first halo sub-implant and the third halo sub-implant is performed, the lateral extent of the first drain side halo implanted region (1060) relative to the first MOS gate (1014) is established by the fourth halo sub-implant (1032). Halo dopants from the fourth halo sub-implant (1032) are shadowed by the first MOS gate (1014), and hence the left edge of the first drain side halo implanted region (1060) is established at a lateral separation from the first MOS gate (1014).

Similarly, a first source side halo implanted region (1062) is formed by the first halo sub-implant, the second halo sub-implant (1028), the third halo sub-implant and the fourth halo sub-implant (1032). The fourth halo sub-implant (1032), if performed, establishes a larger lateral extent of an overlap between the first MOS gate (1014) and the first source side halo implanted region (1062) than the other halo sub-implants, because the fourth halo sub-implant (1032) has the largest angle from the perpendicular axis toward the left direction. If the fourth halo sub-implant (1032) is not performed, the first halo sub-implant, if performed, and/or the third halo sub-implant, if performed, establish a right edge of the first source side halo implanted region (1062) to be substantially aligned with a lateral surface of the first MOS gate (1014) facing the left edge of the integrated circuit (1000), because the first halo sub-implant and the third halo sub-implant are substantially parallel to the left-facing lateral surface of the first MOS gate (1014). If none of the fourth halo sub-implant (1032), the first halo sub-implant and the third halo sub-implant is performed, the lateral extent of the first drain side halo implanted region (1062) relative to the first MOS gate (1014) is established by the second halo sub-implant (1028) at a lateral separation from the first MOS gate (1014).

A first drain side LDD implanted region (1064) is formed by the first LDD sub-implant, not shown in FIG. 1B for clarity, the second LDD sub-implant (1036), the third LDD sub-implant, not shown in FIG. 1B for clarity, and the fourth LDD sub-implant (1040). The second LDD sub-implant (1036), if performed, establishes a larger lateral extent of an overlap between the first MOS gate (1014) and the first drain side LDD implanted region (1064) compared to the other three LDD sub-implants, because the second LDD sub-implant (1036) has the largest angle from the perpendicular axis toward the right direction, and thus implants LDD dopants a certain distance under the first MOS gate (1014). A larger angle of the second LDD sub-implant (1036) from the perpendicular axis produces a larger lateral extent of the overlap between the first MOS gate (1014) and the first drain side LDD implanted region (1064). If the second LDD sub-implant (1036) is not performed, the first LDD sub-implant, if performed, and/or the third LDD sub-implant, if performed, establish a left edge of the first drain side LDD implanted region (1064) to be substantially aligned with the lateral surface of the first MOS gate (1014) facing the right edge of the integrated circuit (1000), because the first LDD sub-implant and the third LDD sub-implant are substantially parallel to a lateral surface of the first MOS gate (1014) facing the right edge of the integrated circuit (1000). If none of the second LDD sub-implant (1036), the first LDD sub-implant and the third LDD sub-implant is performed, the lateral extent of the first drain side LDD implanted region (1064) relative to the first MOS gate (1014) is established by the fourth LDD sub-implant (1040). LDD dopants from the fourth LDD sub-implant (1040) are shadowed by the first MOS gate (1014), and hence the left edge of the first drain side LDD implanted region (1064) is established at a lateral separation from the first MOS gate (1014).

Similarly, a first source side LDD implanted region (1066) is formed by the first LDD sub-implant, the second LDD sub-implant (1036), the third LDD sub-implant and the fourth LDD sub-implant (1040). The fourth LDD sub-implant (1040), if performed, establishes a larger lateral extent of an overlap between the first MOS gate (1014) and the first source side LDD implanted region (1066) than the other LDD sub-implants, because the fourth LDD sub-implant (1040) has the largest angle from the perpendicular axis toward the left direction. If the fourth LDD sub-implant (1040) is not performed, the first LDD sub-implant, if performed, and the third LDD sub-implant, if performed, establish a right edge of the first source side LDD implanted region (1066) to be substantially aligned with a lateral surface of the first MOS gate (1014) facing the left edge of the integrated circuit (1000), because the first LDD sub-implant and the third LDD sub-implant are substantially parallel to the left-facing lateral surface of the first MOS gate (1014). If none of the fourth LDD sub-implant (1040), the first LDD sub-implant and the third LDD sub-implant is performed, the lateral extent of the first source side LDD implanted region (1066) relative to the first MOS gate (1014) is established by the second LDD sub-implant (1036) at a lateral separation from the first MOS gate (1014).

For illustrative purposes, the second halo sub-implant (1028) and the fourth halo sub-implant (1032) are depicted in FIG. 1B as having a larger tilt angle from the perpendicular axis than the second LDD sub-implant (1036) and the fourth LDD sub-implant (1040), resulting in the first drain side halo implanted region (1060) and the first source side halo implanted region (1062) having larger lateral overlaps with the first MOS gate (1014) than the first drain side LDD implanted region (1064) and the first source side LDD implanted region (1066). A depth of the first drain side LDD implanted region (1064) and the first source side LDD implanted region (1066) are depicted as greater than a depth of the first drain side halo implanted region (1060) and the first source side halo implanted region (1062). It is within the scope of the instant invention to form MOS transistors with upper-lower gate longitudinal axes having different lateral overlaps of halo implanted regions and LDD implanted regions with MOS gates and different depths of halo implanted regions and LDD implanted regions, by adjusting tilt angles, doses, energies, and species of halo sub-implants and LDD sub implants.

Gate sidewall spacers are typically formed on lateral surfaces of MOS gates between ion implantation of LDD regions and ion implantation of S/D regions. Gate sidewall spacers are commonly formed by deposition of one or more conformal layers of silicon nitride and/or silicon dioxide, commonly between 50 and 200 nanometers thick, on a top and lateral surfaces of an MOS gate and a top surface of a surrounding substrate, followed by removal of the conformal layer material from the top surface of the MOS gate and the top surface of the substrate by known anisotropic etching methods, leaving the conformal layer material on the lateral surfaces of the MOS gate. In the embodiment depicted in FIG. 1B, a first gate sidewall spacer (1068) is formed on lateral surfaces of the first MOS gate (1014).

A first drain side S/D implanted region (1070) is formed by the first S/D sub-implant, not shown in FIG. 1B for clarity, the second S/D sub-implant (1044), the third S/D sub-implant, not shown in FIG. 1B for clarity, and the fourth S/D sub-implant (1048). The second S/D sub-implant (1044), if performed, establishes a larger lateral extent of an overlap between the first gate sidewall spacer (1068) and the first drain side S/D implanted region (1070) compared to the other three S/D sub-implants, because the second S/D sub-implant (1044) has the largest angle from the perpendicular axis toward the right direction, and thus implants S/D dopants a certain distance under the first gate sidewall spacer (1068). A larger angle of the second S/D sub-implant (1044) from the perpendicular axis produces a larger lateral extent of the overlap between the first gate sidewall spacer (1068) and the first drain side S/D implanted region (1070). If the second S/D sub-implant (1044) is not performed, the first S/D sub-implant, if performed, and/or the third S/D sub-implant, if performed, establish a left edge of the first drain side S/D implanted region (1070) to be substantially aligned with a right edge of the first gate sidewall spacer (1068), because the first S/D sub-implant and the third S/D sub-implant are substantially parallel to the a right edge of the first gate sidewall spacer (1068). If none of the second S/D sub-implant (1044), the first S/D sub-implant and the third S/D sub-implant is performed, the lateral extent of the first drain side S/D implanted region (1070) relative to the first gate sidewall spacer (1068) is established by the fourth S/D sub-implant (1048). S/D dopants from the fourth S/D sub-implant (1048) are shadowed by the first gate sidewall spacer (1068), and hence the left edge of the first drain side S/D implanted region (1070) is established at a lateral separation from the first gate sidewall spacer (1068).

Similarly, a first source side S/D implanted region (1072) is formed by the first S/D sub-implant, the second S/D sub-implant (1044), the third S/D sub-implant and the fourth S/D sub-implant (1048). The fourth S/D sub-implant (1048), if performed, establishes a larger lateral extent of an overlap between the first gate sidewall spacer (1068) and the first source side S/D implanted region (1072) than the other S/D sub-implants, because the fourth S/D sub-implant (1048) has the largest angle from the perpendicular axis toward the left direction. If the fourth S/D sub-implant (1048) is not performed, the first S/D sub-implant, if performed, and the third S/D sub-implant, if performed, establish a right edge of the first source side S/D implanted region (1072) to be substantially aligned with a left edge of the first gate sidewall spacer (1068), because the first S/D sub-implant and the third S/D sub-implant are substantially parallel to the left edge of the first gate sidewall spacer (1068). If none of the fourth S/D sub-implant (1048), the first S/D sub-implant and the third S/D sub-implant is performed, the lateral extent of the first source side S/D implanted region (1072) relative to the first gate sidewall spacer (1068) is established by the second S/D sub-implant (1044) at a lateral separation from the first gate sidewall spacer (1068).

Referring to FIG. 1C, the second type of MOS transistor (1012) is formed on the substrate (1050) as described in reference to FIG. 1B. Elements of field oxide (1052) may be formed at a top surface of the substrate (1050), as described in reference to FIG. 1B. A second well (1074) may be formed in the substrate (1050), as described in reference to FIG. 1B, in a region defined for the second type of MOS transistor (1012). The second type of MOS transistor (1012) includes a second gate dielectric layer (1076), formed on a top surface of the substrate (1050), as described in reference to FIG. 1B and possibly concurrently with the first gate dielectric layer (1056). The second MOS gate (1016) is formed on a top surface of the second gate dielectric layer (1076), as described in reference to FIG. 1B and possibly concurrently with the first MOS gate (1014).

A second drain side halo implanted region (1080) is formed by the first halo sub-implant (1026), the second halo sub-implant, not shown in FIG. 1C for clarity, the third halo sub-implant (1030), and the fourth halo sub-implant, not shown in FIG. 1C for clarity. The first halo sub-implant (1026), if performed, establishes a larger lateral extent of the overlap between the second MOS gate (1016) and the second drain side halo implanted region (1080) compared to the other three halo sub-implants, because the first halo sub-implant (1026) has the largest angle from the perpendicular axis toward the upper direction, and thus implants halo dopants a certain distance under the second MOS gate (1016). A larger angle of the first halo sub-implant (1026) from the perpendicular axis produces a larger lateral extent of the overlap between the second MOS gate (1016) and the second drain side halo implanted region (1080). If the first halo sub-implant (1026) is not performed, the second halo sub-implant, if performed, and/or the fourth halo sub-implant, if performed, establish the lower edge of the second drain side halo implanted region (1080) to be substantially aligned with the lateral surface of the second MOS gate (1016) facing the top edge of the integrated circuit (1000), because the second halo sub-implant and the fourth halo sub-implant are substantially parallel to the lateral surface of the second MOS gate (1016) facing the right edge of the integrated circuit (1000). If none of the first halo sub-implant (1026), the second halo sub-implant and the fourth halo sub-implant is performed, the lateral extent of the second drain side halo implanted region (1080) relative to the second MOS gate (1016) is established by the third halo sub-implant (1030). Halo dopants from the third halo sub-implant (1030) are shadowed by the second MOS gate (1016), and hence the lower edge of the second drain side halo implanted region (1080) is established at a lateral separation from the second MOS gate (1016).

Similarly, a second source side halo implanted region (1082) is formed by the first halo sub-implant (1026), the second halo sub-implant, the third halo sub-implant (1030) and the fourth halo sub-implant. The third halo sub-implant (1030), if performed, establishes a larger lateral extent of an overlap between the second MOS gate (1016) and the second source side halo implanted region (1082) than the other halo sub-implants, because the third halo sub-implant (1030) has the largest angle from the perpendicular axis toward the lower direction. If the third halo sub-implant (1030) is not performed, the second halo sub-implant, if performed, and/or the fourth halo sub-implant, if performed, establish an upper edge of the second source side halo implanted region (1082) to be substantially aligned with a lateral surface of the second MOS gate (1016) facing the lower edge of the integrated circuit (1000), because the second halo sub-implant and the fourth halo sub-implant are substantially parallel to the lower-facing lateral surface of the second MOS gate (1016). If none of the third halo sub-implant (1030), the second halo sub-implant and the fourth halo sub-implant is performed, the lateral extent of the second drain side halo implanted region (1082) relative to the second MOS gate (1016) is established by the first halo sub-implant (1026) at a lateral separation from the second MOS gate (1016).

For illustrative purposes, the first halo sub-implant (1026) is depicted in FIG. 1C as having a larger tilt angle from the perpendicular axis than the third halo sub-implant (1030), and correspondingly, the second drain side halo implanted region (1080) is depicted as having a larger overlap with the second MOS gate (1016) than the second source side halo implanted region (1082). In other embodiments, overlaps between the second drain side halo implanted region (1080) and the second MOS gate (1016), and between the second source side halo implanted region (1082) and the second MOS gate (1016) may be varied to provide desired transistor properties such as capacitance between gate and source, on-state current, off-state leakage, and threshold potential.

A second drain side LDD implanted region (1084) is formed by the first LDD sub-implant (1034), the second LDD sub-implant, not shown in FIG. 1C for clarity, the third LDD sub-implant (1038), and the fourth LDD sub-implant, not shown in FIG. 1C for clarity. The first LDD sub-implant (1034), if performed, establishes a larger lateral extent of an overlap between the second MOS gate (1016) and the second drain side LDD implanted region (1084) compared to the other three LDD sub-implants, because the first LDD sub-implant (1034) has the largest angle from the perpendicular axis toward the lower direction, and thus implants LDD dopants a certain distance under the second MOS gate (1016). If the first LDD sub-implant (1034) is not performed, the second LDD sub-implant, if performed, and/or the fourth LDD sub-implant, if performed, establish a lower edge of the second drain side LDD implanted region (1084) to be substantially aligned with the lateral surface of the second MOS gate (1016) facing the upper edge of the integrated circuit (1000), because the second LDD sub-implant and the fourth LDD sub-implant are substantially parallel to a lateral surface of the second MOS gate (1016) facing the upper edge of the integrated circuit (1000). If none of the first LDD sub-implant (1034), the second LDD sub-implant and the fourth LDD sub-implant is performed, the lateral extent of the second drain side LDD implanted region (1064) relative to the second MOS gate (1016) and is established by the third LDD sub-implant (1038). LDD dopants from the third LDD sub-implant (1038) are shadowed by the second MOS gate (1016), and hence the lower edge of the second drain side LDD implanted region (1084) is established at a lateral separation from the second MOS gate (1016).

Similarly, a second source side LDD implanted region (1086) is formed by the first LDD sub-implant (1034), the second LDD sub-implant, the third LDD sub-implant (1038) and the fourth LDD sub-implant. The third LDD sub-implant (1038), if performed, establishes a larger lateral extent of an overlap between the second MOS gate (1016) and the second source side LDD implanted region (1086) than the other LDD sub-implants, because the third LDD sub-implant (1038) has the largest angle from the perpendicular axis toward the lower direction. If the third LDD sub-implant (1038) is not performed, the second LDD sub-implant, if performed, and the fourth LDD sub-implant, if performed, establish an upper edge of the second source side LDD implanted region (1086) to be substantially aligned with a lateral surface of the second MOS gate (1016) facing the lower edge of the integrated circuit (1000), because the second LDD sub-implant and the fourth LDD sub-implant are substantially parallel to the lower-facing lateral surface of the second MOS gate (1016). If none of the third LDD sub-implant (1038), the second LDD sub-implant and the fourth LDD sub-implant is performed, the lateral extent of the second source side LDD implanted region (1086) relative to the second MOS gate (1016) is established by the first LDD sub-implant (1034) at a lateral separation from the second MOS gate (1016).

For illustrative purposes, the first halo sub-implant (1026) and the third halo sub-implant (1030) are depicted in FIG. 1C as having a larger tilt angle from the perpendicular axis than the first LDD sub-implant (1034) and the third LDD sub-implant (1038), resulting in the second drain side halo implanted region (1080) and the second source side halo implanted region (1082) having larger lateral overlaps with the second MOS gate (1016) than the second drain side LDD implanted region (1084) and the second source side LDD implanted region (1086). A depth of the second drain side LDD implanted region (1084) and the second source side LDD implanted region (1086) are depicted as greater than a depth of the second drain side halo implanted region (1080) and the second source side halo implanted region (1082). It is within the scope of the instant invention to form MOS transistors with left-right gate longitudinal axes having different lateral overlaps of halo implanted regions and LDD implanted regions with MOS gates and different depths of halo implanted regions and LDD implanted regions, by adjusting tilt angles, doses, energies, and species of halo sub-implants and LDD sub implants.

In the embodiment depicted in FIG. 1C, a second gate sidewall spacer (1088) is formed on lateral surfaces of the second MOS gate (1016), as described in reference to FIG. 1B. A second drain side S/D implanted region (1090) is formed by the first S/D sub-implant (1042), the second S/D sub-implant, not shown in FIG. 1C for clarity, the third S/D sub-implant (1046), and the fourth S/D sub-implant, not shown in FIG. 1C for clarity. The first S/D sub-implant (1042), if performed, establishes a larger lateral extent of an overlap between the second gate sidewall spacer (1088) and the second drain side S/D implanted region (1090) compared to the other three S/D sub-implants, because the first S/D sub-implant (1042) has the largest angle from the perpendicular axis toward the upper direction, and thus implants S/D dopants a certain distance under the second gate sidewall spacer (1088). A larger angle of the first S/D sub-implant (1042) from the perpendicular axis produces a larger lateral extent of the overlap between the second gate sidewall spacer (1088) and the second drain side S/D implanted region (1090). If the first S/D sub-implant (1042) is not performed, the second S/D sub-implant, if performed, and/or the fourth S/D sub-implant, if performed, establish a lower edge of the second drain side S/D implanted region (1090) to be substantially aligned with an upper edge of the second gate sidewall spacer (1088), because the second S/D sub-implant and the fourth S/D sub-implant are substantially parallel to the lower edge of the second drain side S/D implanted region (1090). If none of the first S/D sub-implant (1042), the second S/D sub-implant and the fourth S/D sub-implant is performed, the lateral extent of the second drain side S/D implanted region (1090) relative to the second gate sidewall spacer (1088) is established by the third S/D sub-implant (1046). S/D dopants from the third S/D sub-implant (1046) are shadowed by the second gate sidewall spacer (1088), and hence the lower edge of the first drain side S/D implanted region (1090) is established at a lateral separation from the second gate sidewall spacer (1088).

Similarly, a second source side S/D implanted region (1092) is formed by the first S/D sub-implant (1042), the second S/D sub-implant, the third S/D sub-implant (1046) and the fourth S/D sub-implant. The third S/D sub-implant (1046), if performed, establishes a larger lateral extent of an overlap between the second gate sidewall spacer (1088) and the second source side S/D implanted region (1092) than the other S/D sub-implants, because the third S/D sub-implant (1046) has the largest angle from the perpendicular axis toward the lower direction. If the third S/D sub-implant (1046) is not performed, the second S/D sub-implant, if performed, and the fourth S/D sub-implant, if performed, establish an upper edge of the second source side S/D implanted region (1092) to be substantially aligned with a lower edge of the second gate sidewall spacer (1088), because the second S/D sub-implant and the second S/D sub-implant are substantially parallel to the lower edge of the second gate sidewall spacer (1088). If none of the third S/D sub-implant (1046), the second S/D sub-implant and the fourth S/D sub-implant is performed, the lateral extent of the second source side S/D implanted region (1092) relative to the second gate sidewall spacer (1088) is established by the first S/D sub-implant (1042) at a lateral separation from the second gate sidewall spacer (1088).

As a result of a difference or differences in tilt angles, doses, energies and dopant species between the halo sub-implants and/or LDD sub-implants and/or S/D sub-implants, there exists at least one difference between the first MOS transistor (1010) and the second MOS transistor (1012) with regard to the first drain and source halo implanted regions (1060, 1062) compared to the second drain and source halo implanted regions (1080, 1082), and/or the first drain and source LDD implanted regions (1064, 1066) compared to the second drain and source LDD implanted regions (1084, 1086), and/or the first drain and source S/D implanted regions (1070, 1072) compared to the second drain and source S/D implanted regions (1090, 1092). As a result of at least one difference between the first MOS transistor (1010) and the second MOS transistor (1012) with regard to the implanted regions recited above, there exists at least one difference in electrical parameters of the first MOS transistor (1010) and the second MOS transistor (1012), including, but not limited to, capacitance between gate and source, on-state current, off-state leakage, and threshold potential.

It will be recognized by those familiar with integrated circuit fabrication that the advantages of the embodiment discussed in reference to FIG. 1A through FIG. 1C may be realized by similar embodiments in which relative positions of drain and source areas are exchanged, with appropriate changes to angled sub-implants.

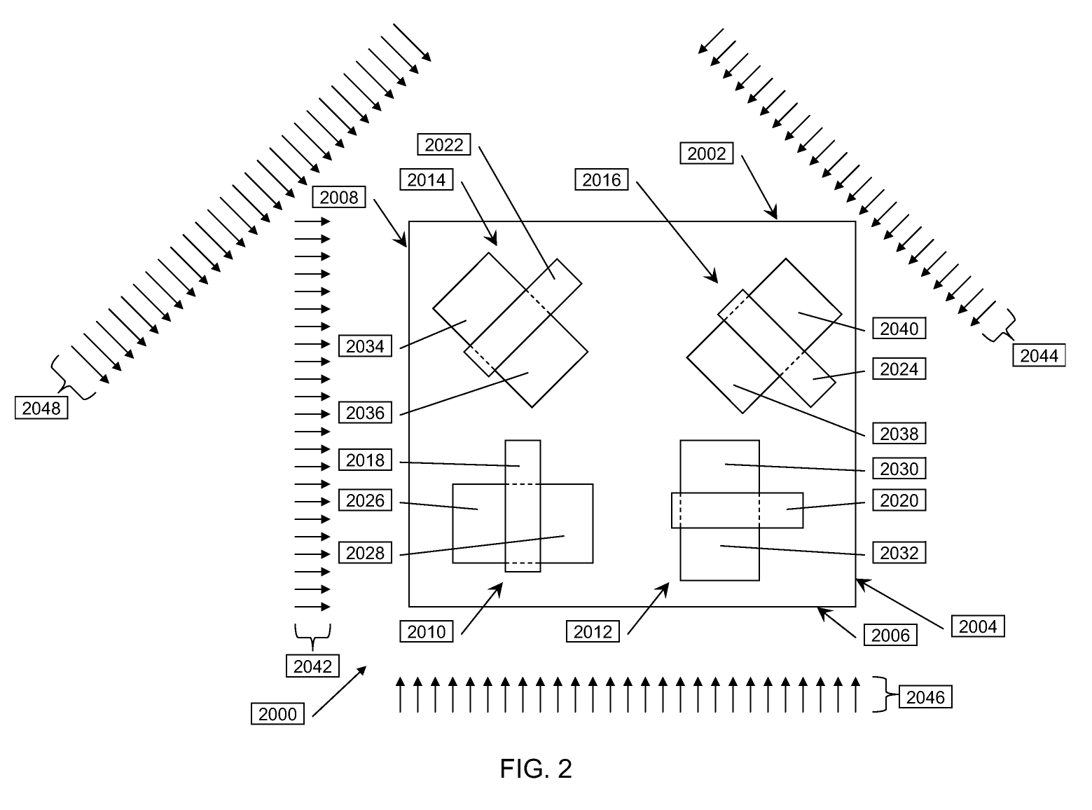

FIG. 2 is a top view of an alternate embodiment of the instant invention, depicted during an ion implantation process. An integrated circuit (2000) has an upper edge (2002), a right edge (2004), a lower edge (2006) and a left edge (2008). The integrated circuit contains a first type of MOS transistor (2010), a second type of MOS transistor (2012), a third type of MOS transistor (2014) and a fourth type of MOS transistor (2016). Other components in the integrated circuit (2000) are not shown in FIG. 2 for clarity. The first type of MOS transistor (2010) has a first gate (2018) with an upper-lower longitudinal axis. The second type of MOS transistor (2012) has a second gate (2020) with a left-right longitudinal axis. The third type of MOS transistor (2014) has a third gate (2022) with a longitudinal axis oriented along an upper-right to lower-left direction. The fourth type of MOS transistor (2016) has a fourth gate (2024) with a longitudinal axis oriented along an upper-left to lower-right direction. Offset and sidewall spacers are not shown in FIG. 2 for clarity. The first type of MOS transistor (2010) includes a first source area (2026) adjacent to the first gate (2018), and a first drain area (2028) adjacent to the first gate (2018) opposite the first source area (2026). The second type of MOS transistor (2012) includes a second source area (2030) adjacent to the second gate (2020), and a second drain area (2032) adjacent to the second gate (2020) opposite the second source area (2030). The third type of MOS transistor (2014) includes a third source area (2034) adjacent to the third gate (2022), and a third drain area (2036) adjacent to the third gate (2022) opposite the third source area (2034). The fourth type of MOS transistor (2016) includes a fourth source area (2038) adjacent to the fourth gate (2024), and a fourth drain area (2040) adjacent to the fourth gate (2024) opposite the fourth source area (2038).

The first type of MOS transistor (2010), the second type of MOS transistor (2012), the third type of MOS transistor (2014) and the fourth type of transistor (2016) are formed using halo, LDD and S/D ion implant processes, which produce halo, LDD and S/D ion implanted layers at a top surface of the integrated circuit (2000). In the instant embodiment, at least one of the halo, LDD and S/D ion implant processes is performed using two or more sub-implants which are tilted from an axis perpendicular to the top surface of the integrated circuit (2000). In the instant embodiment, at least one of the sub-implants is tilted parallel to an edge of the integrated circuit (2000), and at least one of the sub-implants is tilted in a direction which is 45 degrees from parallel to an edge of the integrated circuit (2000). One of the halo, LDD and S/D ion implant processes is depicted in FIG. 2 as a first sub-implant (2042), a second sub-implant (2044), an optional third sub-implant (2046) and an optional fourth sub-implant (2048). The first sub-implant (2042) is tilted from the perpendicular axis toward a left direction. The second sub-implant (2044) is tilted from the perpendicular axis toward an upper-right direction. The optional third sub-implant (2046) is tilted from the perpendicular axis toward a lower direction. The optional fourth sub-implant (2048) is tilted from the perpendicular axis toward an upper-left direction. Additional sub-implants may be performed as part of the ion implant process depicted in FIG. 2. Tilt angles, doses, energies and dopant species may differ between the sub-implants.

A first implanted source region is formed in the first source area (2026) by the first sub-implant (2042), the second sub-implant (2044), the optional third sub-implant (2046), if performed, and the optional fourth sub-implant (2048), if performed. A lateral extent of an overlap or separation between the first implanted source region in the first source area (2026) and the first gate (2018) is established by the tilt angles, doses, energies and dopant species of the sub-implants (2042, 2044, 2046, 2048). Similarly, a first implanted drain region is formed in the first drain area (2028). A lateral extent of an overlap or separation between the first implanted drain region in the first drain area (2028) and the first gate (2018) is likewise established by the tilt angles, doses, energies and dopant species of the sub-implants (2042, 2044, 2046, 2048), and may differ from the lateral extent of an overlap or separation between the first implanted source region in the first source area (2026) and the first gate (2018), due to differences in the tilt angles, doses, energies and dopant species of the sub-implants (2042, 2044, 2046, 2048).

Corresponding differences between a second implanted source region formed in the second source area (2030) and a second implanted drain region formed in the second drain area (2032) may occur due to the differences in the tilt angles, doses, energies and dopant species of the sub-implants (2042, 2044, 2046, 2048).

Corresponding differences between a third implanted source region formed in the third source area (2034) and a third implanted drain region formed in the third drain area (2036), and between a fourth implanted source region formed in the fourth source area (2038) and a fourth implanted drain region formed in the fourth drain area (2040) may also occur due to the differences in the tilt angles, doses, energies and dopant species of the sub-implants (2042, 2044, 2046, 2048).

Furthermore, as a result of a difference or differences in tilt angles, doses, energies and dopant species between the sub-implants (2042, 2044, 2046, 2048), there exists at least one difference between each of the first type of MOS transistor (2010), the second type of MOS transistor (2012), the third type of MOS transistor (2014) and the fourth type of transistor (2016) with regard to the first drain and source halo implanted regions, the second drain and source halo implanted regions, the third drain and source halo implanted regions and the fourth drain and source halo implanted regions. As a result of the cited differences between the first type of MOS transistor (2010), the second type of MOS transistor (2012), the third type of MOS transistor (2014) and the fourth type of transistor (2016) with regard to the implanted regions recited above, there exists at least one difference in electrical parameters of the first type of MOS transistor (2010), the second type of MOS transistor (2012), the third type of MOS transistor (2014) and the fourth type of transistor (2016), including, but not limited to, capacitance between gate and source, on-state current, off-state leakage, and threshold potential.

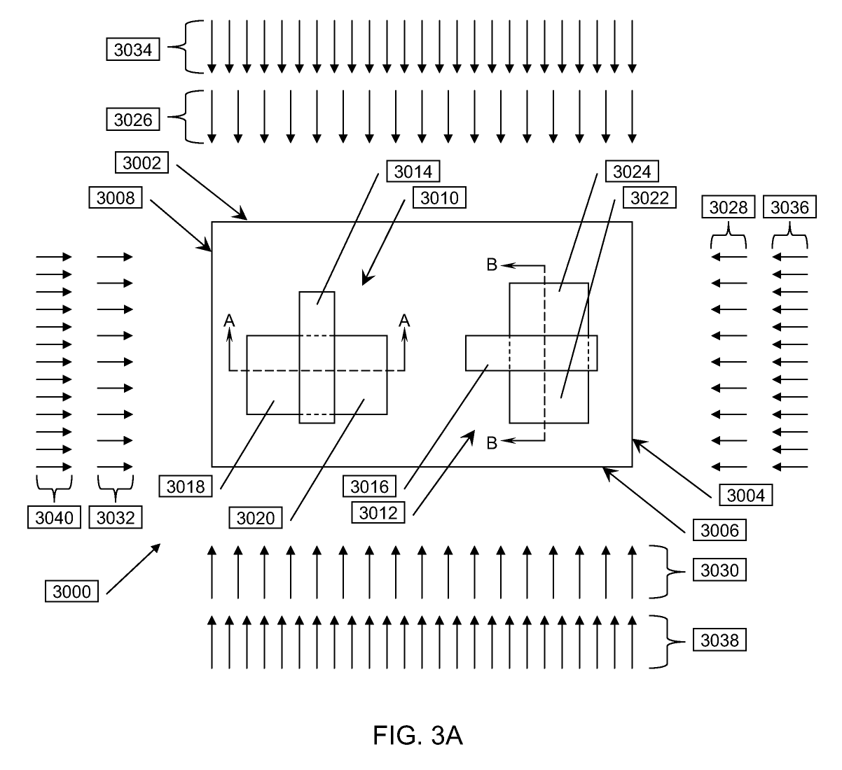

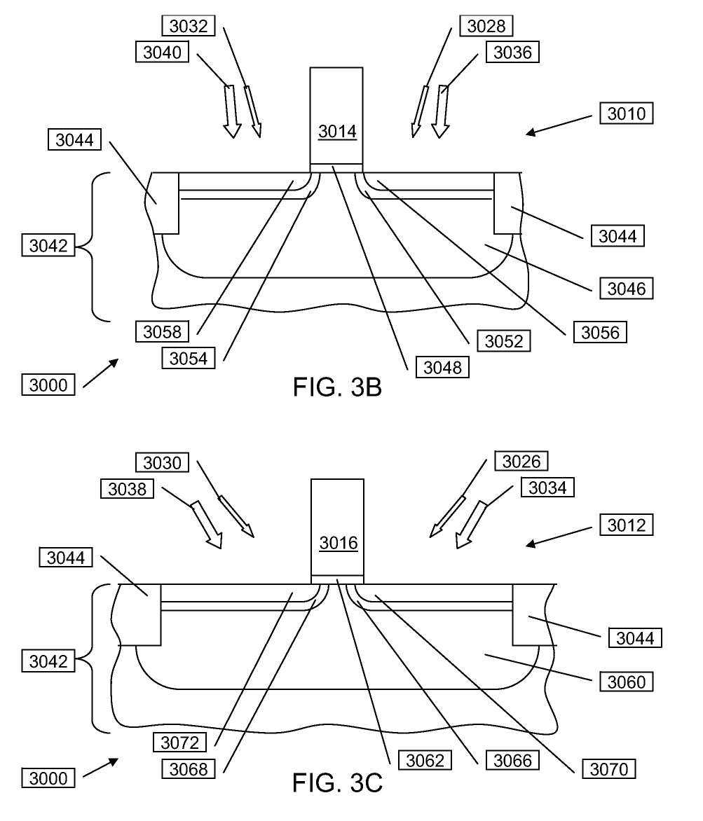

FIG. 3A through FIG. 3C depict an integrated circuit containing a first transistor and a second transistor formed according to a first specific embodiment of the instant invention. FIG. 3A is a top view of the integrated circuit (3000) with an upper edge (3002), a right edge (3004), a lower edge (3006) and a left edge (3008). The integrated circuit contains a first transistor (3010) and a second transistor (3012). The first transistor (3010) has a first gate (3014) with an upper-lower longitudinal axis. The second transistor (3012) has a second gate (3016) with a left-right longitudinal axis. The first transistor (3010) includes a first source area (3018) adjacent to, and on a left side of, the first gate (3014), and a first drain area (3020) adjacent to the first gate (3014) opposite the first source area (3018). The second transistor (3012) includes a second source area (3022) adjacent to, and on a lower side of, the second gate (3016), and a second drain area (3024) adjacent to the second gate (3016) opposite the second source area (3022). Other components in the integrated circuit (3000) are not shown in FIG. 3A for clarity.

The first transistor (3010) and the second transistor (3012) are formed using halo and LDD ion implant processes which include angled sub-implants to produce halo and LDD ion implanted layers at a top surface of the integrated circuit (3000). The halo ion implant process includes a first halo sub-implant (3026) angled toward the upper direction, a second halo sub-implant (3028) angled toward the right direction, a third halo sub-implant (3030) angled toward the lower direction, and a fourth halo sub-implant (3032) angled toward the left direction. A tilt angle of the first halo sub-implant (3026) from an axis perpendicular to the top surface of the integrated circuit (3000) is substantially equal to a tilt angle of the third halo sub-implant (3030), and a tilt angle of the second halo sub-implant (3028) is substantially equal to a tilt angle of the fourth halo sub-implant (3032). The tilt angle of the first and third halo sub-implants (3026, 3030) are greater than the tilt angle of the second and fourth halo sub-implants (3028, 3032). In a further embodiment, an energy of the first halo sub-implant (3026) may be substantially equal to an energy of the third halo sub-implant (3030), and an energy of the second halo sub-implant (3028) may be substantially equal to an energy of the fourth halo sub-implant (3032), while the energy of the first and third halo sub-implants (3026, 3030) may be greater than the energy of the second and fourth halo sub-implants (3028, 3032). In yet another embodiment, a dose of the first halo sub-implant (3026) may be substantially equal to a dose of the third halo sub-implant (3030), and a dose of the second halo sub-implant (3028) may be substantially equal to a dose of the fourth halo sub-implant (3032), while the dose of the first and third halo sub-implants (3026, 3030) may be greater than the dose of the second and fourth halo sub-implants (3028, 3032).

Similarly, the LDD ion implant process includes a first LDD sub-implant (3034) angled toward the upper direction, a second LDD sub-implant (3036) angled toward the right direction, a third LDD sub-implant (3038) angled toward the lower direction, and a fourth LDD sub-implant (3040) angled toward the left direction. A tilt angle of the first LDD sub-implant (3034) from an axis perpendicular to the top surface of the integrated circuit (3000) is substantially equal to a tilt angle of the third LDD sub-implant (3038), and a tilt angle of the second LDD sub-implant (3036) is substantially equal to a tilt angle of the fourth LDD sub-implant (3040). The tilt angle of the first and third LDD sub-implants (3034, 3038) are greater than the tilt angle of the second and fourth LDD sub-implants (3036, 3040). In a further embodiment, an energy of the first LDD sub-implant (3034) may be substantially equal to an energy of the third LDD sub-implant (3038), and an energy of the second LDD sub-implant (3036) may be substantially equal to an energy of the fourth LDD sub-implant (3040), while the energy of the first and third LDD sub-implants (3034, 3038) may be greater than the energy of the second and fourth LDD sub-implants (3036, 3040). In yet another embodiment, a dose of the first LDD sub-implant (3034) may be substantially equal to a dose of the third LDD sub-implant (3038), and a dose of the second LDD sub-implant (3036) may be substantially equal to a dose of the fourth LDD sub-implant (3040), while the dose of the first and third LDD sub-implants (3034, 3038) may be greater than the dose of the second and fourth LDD sub-implants (3036, 3040).

FIG. 3B and FIG. 3C are cross-sections of the integrated circuit (3000), through the first transistor (3010) and the second transistor (3012) depicted in FIG. 3A. FIG. 3B depicts a cross-section at section line A-A of FIG. 3A. FIG. 3C depicts a cross-section at section line B-B of FIG. 3A. Referring to FIG. 3B, the first transistor (3010) is formed on a substrate (3042) of the integrated circuit (3000), as described in reference to FIG. 1B. Elements of field oxide (3044) may be formed at a top surface of the substrate (3042), as described in reference to FIG. 1B. A first well (3046) may be formed in the substrate (3042), as described in reference to FIG. 1B. The first transistor (3010) includes a first gate dielectric layer (3048), formed on a top surface of the substrate (3042) as described in reference to FIG. 1B. A first gate (3014) is formed on a top surface of the first gate dielectric layer (3048), as described in reference to FIG. 1A.

A first drain side halo implanted region (3052) and a first source side halo implanted region (3054) are formed by the first halo sub-implant, not shown in FIG. 3B for clarity, the second halo sub-implant (3028), the third halo sub-implant, not shown in FIG. 3B for clarity, and the fourth halo sub-implant (3032). Spatial distributions of halo dopants in the first drain side halo implanted region (3052) and the first source side halo implanted region (3054) are established by the angles, doses and energies of the halo sub-implants. Because the first and third halo sub-implants are symmetric with respect to the upper-lower longitudinal axis of the first gate (3014), and because the second halo sub-implant (3028) and the fourth halo sub-implant (3032) have substantially equal angles, doses and energies, the first drain side halo implanted region (3052) and the first source side halo implanted region (3054) are substantially symmetric with respect to the first gate (3014). A drain side lateral overlap of the first drain side halo implanted region (3052) with the first gate (3014) is substantially equal to a source side lateral overlap of the first source side halo implanted region (3054) with the first gate (3014).

A first drain side LDD implanted region (3056) and a first source side LDD implanted region (3058) are formed by the first LDD sub-implant, not shown in FIG. 3B for clarity, the second LDD sub-implant (3036), the third LDD sub-implant, not shown in FIG. 3B for clarity, and the fourth LDD sub-implant (3040). Spatial distributions of LDD dopants in the first drain side LDD implanted region (3056) and the first source side LDD implanted region (3058) are established by the angles, doses and energies of the LDD sub-implants. Because the first and third LDD sub-implants are symmetric with respect to the upper-lower longitudinal axis of the first gate (3014), and because the second LDD sub-implant (3036) and the fourth LDD sub-implant (3040) have substantially equal angles, doses and energies, the first drain side LDD implanted region (3056) and the first source side LDD implanted region (3058) are substantially symmetric with respect to the first gate (3014). A drain side lateral overlap of the first drain side LDD implanted region (3056) with the first gate (3014) is substantially equal to a source side lateral overlap of the first source side LDD implanted region (3058) with the first gate (3014).

For illustrative purposes, the second halo sub-implant (3028) and the fourth halo sub-implant (3032) are depicted in FIG. 3B as having a larger tilt angle from the perpendicular axis than the second LDD sub-implant (3036) and the fourth LDD sub-implant (3040), resulting in the first drain side halo implanted region (3052) and the first source side halo implanted region (3054) having larger lateral overlaps with the first gate (3014) than the first drain side LDD implanted region (3056) and the first source side LDD implanted region (3058). A depth of the first drain side LDD implanted region (3056) and the first source side LDD implanted region (3058) are depicted as less than a depth of the first drain side halo implanted region (3052) and the first source side halo implanted region (3054). It is within the scope of the instant invention to form first transistors with upper-lower gate longitudinal axes having different lateral overlaps of halo implanted regions and LDD implanted regions with first gates and different depths of halo implanted regions and LDD implanted regions, by adjusting tilt angles, doses, energies, and species of halo sub-implants and LDD sub implants.

Referring to FIG. 3C, the second transistor (3012) is formed on the substrate (3042) of the integrated circuit (3000), as described in reference to FIG. 1A. Elements of field oxide (3044) may be formed at a top surface of the substrate (3042), as described in reference to FIG. 1C. A second well (3060) may be formed in the substrate (3042), as described in reference to FIG. 1C. The second transistor (3012) includes a second gate dielectric layer (3062), formed on a top surface of the substrate (3042) as described in reference to FIG. 1C. A second gate (3016) is formed on a top surface of the second gate dielectric layer (3062), as described in reference to FIG. 1A.

A second drain side halo implanted region (3066) and a second source side halo implanted region (3068) are formed by the first halo sub-implant (3026), the second halo sub-implant, not shown in FIG. 3C for clarity, the third halo sub-implant (3030), and the fourth halo sub-implant, not shown in FIG. 3C for clarity. Spatial distributions of halo dopants in the second drain side halo implanted region (3066) and the first source side halo implanted region (3068) are established by the angles, doses and energies of the halo sub-implants. Because the second and fourth halo sub-implants are symmetric with respect to the left-right longitudinal axis of the second gate (3016), and because the first halo sub-implant (3026) and the third halo sub-implant (3030) have substantially equal angles, doses and energies, the second drain side halo implanted region (3066) and the second source side halo implanted region (3068) are substantially symmetric with respect to the second gate (3016). A drain side lateral overlap of the second drain side halo implanted region (3066) with the second gate (3016) is substantially equal to a source side lateral overlap of the second source side halo implanted region (3068) with the second gate (3016).

A second drain side LDD implanted region (3070) and a second source side LDD implanted region (3072) are formed by the first LDD sub-implant (3034), the second LDD sub-implant, not shown in FIG. 3C for clarity, the third LDD sub-implant (3038) and the fourth LDD sub-implant, not shown in FIG. 3C for clarity. Spatial distributions of LDD dopants in the second drain side LDD implanted region (3070) and the first source side LDD implanted region (3072) are established by the angles, doses and energies of the LDD sub-implants. Because the second and fourth LDD sub-implants are symmetric with respect to the left-right longitudinal axis of the second gate (3016), and because the first LDD sub-implant (3034) and the third LDD sub-implant (3038) have substantially equal angles, doses and energies, the second drain side LDD implanted region (3070) and the second source side LDD implanted region (3072) are substantially symmetric with respect to the second gate (3016). A drain side lateral overlap of the second drain side LDD implanted region (3070) with the second gate (3016) is substantially equal to a source side lateral overlap of the second source side LDD implanted region (3072) with the second gate (3016).

For illustrative purposes, the first halo sub-implant (3026) and the third halo sub-implant (3030) are depicted in FIG. 3C as having a larger tilt angle from the perpendicular axis than the first LDD sub-implant (3034) and the third LDD sub-implant (3038), resulting in the second drain side halo implanted region (3066) and the second source side halo implanted region (3068) having larger lateral overlaps with the second gate (3016) than the second drain side LDD implanted region (3070) and the second source side LDD implanted region (3072). A depth of the second drain side LDD implanted region (3070) and the second source side LDD implanted region (3072) are depicted as less than a depth of the second drain side halo implanted region (3066) and the second source side halo implanted region (3068). It is within the scope of the instant invention to form second transistors with upper-lower gate longitudinal axes having different lateral overlaps of halo implanted regions and LDD implanted regions with second gates and different depths of halo implanted regions and LDD implanted regions, by adjusting tilt angles, doses, energies, and species of halo sub-implants and LDD sub implants.

Referring to FIG. 3A through FIG. 3C collectively, in the instant embodiment, the lateral overlaps between the second gate (3016) and the second drain side and source side halo implanted region (3066, 3068) are greater than the lateral overlaps between the first gate (3014) and the first drain side and source side halo implanted regions (3052, 3054), due to the greater tilt angle of the first and third halo sub-implants (3026, 3030) compared to the second and fourth halo sub-implants (3028, 3032). Similarly, the lateral overlaps between the second gate (3016) and the second drain side and source side LDD implanted region (3070, 3072) are greater than the lateral overlaps between the first gate (3014) and the first drain side and source side LDD implanted regions (3056, 3058), due to the greater tilt angle of the first and third LDD sub-implants (3034, 3038) compared to the second and fourth LDD sub-implants (3036, 3040). Providing larger halo and LDD overlaps in the second transistor (3012) concurrently with providing smaller halo and LDD overlaps in the first transistor (3010) in the integrated circuit (3000) may advantageously attain desired tradeoffs of on-state current and off-state leakage in the first transistor (3010) and the second transistor (3012) while reducing fabrication cost and fabrication complexity of the integrated circuit (3000).

It will be recognized by those familiar with integrated circuit fabrication that the advantages of the embodiment discussed in reference to FIG. 3A through FIG. 3C may be realized by similar embodiments in which relative positions of drain and source areas are exchanged, with appropriate changes to angled sub-implants. It will be recognized by those familiar with integrated circuit fabrication that the advantages of the embodiment discussed in reference to FIG. 3A through FIG. 3C may be realized by similar embodiments in which relative orientations of the first transistor (3010) and the second transistor (3012) are exchanged, with appropriate changes to angled sub-implants.

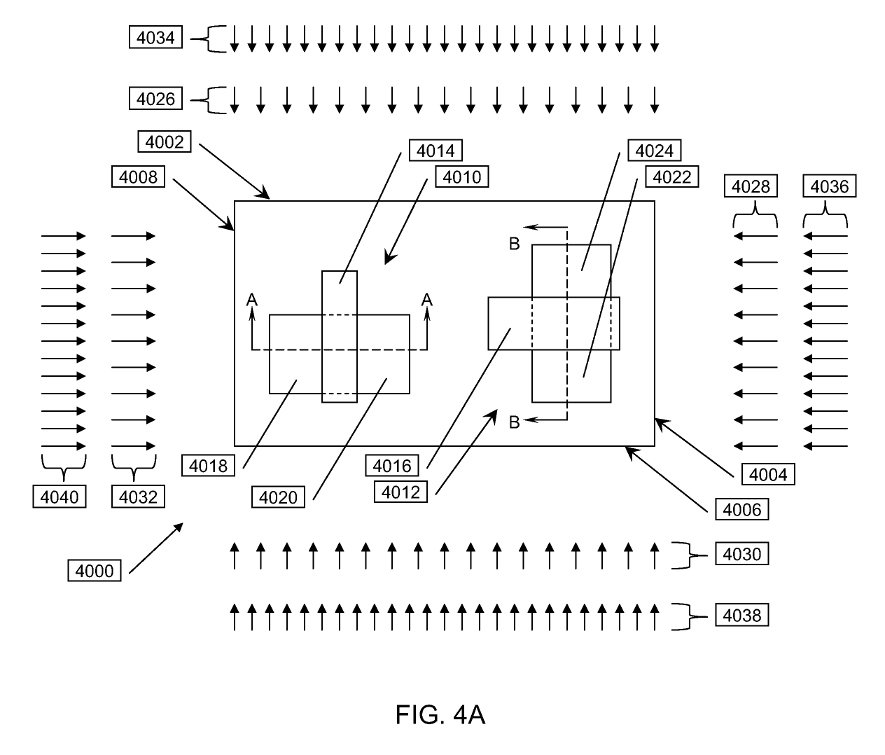

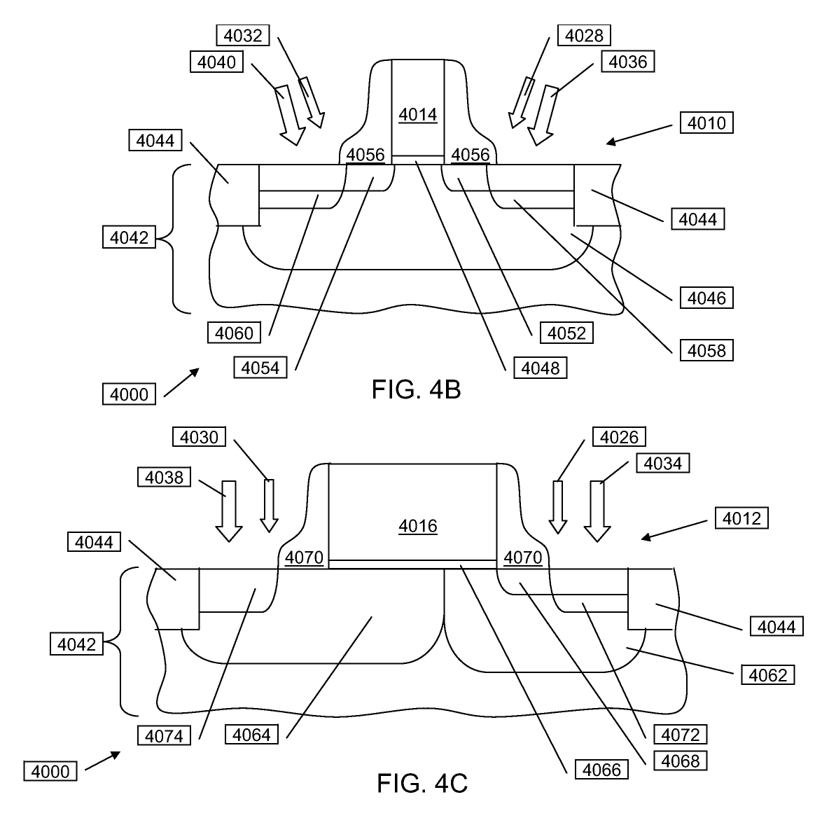

FIG. 4A through FIG. 4C depict an integrated circuit containing a first transistor and a second transistor, possibly a drain extended MOS (DMOS) transistor, formed according to a second specific embodiment of the instant invention. FIG. 4A is a top view of the integrated circuit (4000) with an upper edge (4002), a right edge (4004), a

The first transistor (4010) and the second transistor (4012) are formed using LDD and S/D ion implant processes which include angled sub-implants to produce LDD and S/D ion implanted layers at a top surface of the integrated circuit (4000). The LDD ion implant process includes a first LDD sub-implant (4026) angled toward the upper direction, a second LDD sub-implant (4028) angled toward the right direction, a third LDD sub-implant (4030) angled toward the lower direction, and a fourth LDD sub-implant (4032) angled toward the left direction. A tilt angle of the first LDD sub-implant (4026) from an axis perpendicular to the top surface of the integrated circuit (4000) is substantially equal to a tilt angle of the third LDD sub-implant (4030), and a tilt angle of the second LDD sub-implant (4028) is substantially equal to a tilt angle of the fourth LDD sub-implant (4032). The tilt angle of the first and third LDD sub-implants (4026, 3030) are less than the tilt angle of the second and fourth LDD sub-implants (4028, 3032). In a further embodiment, an energy of the first LDD sub-implant (4026) may be substantially equal to an energy of the third LDD sub-implant (4030), and an energy of the second LDD sub-implant (4028) may be substantially equal to an energy of the fourth LDD sub-implant (4032), while the energy of the first and third LDD sub-implants (4026, 3030) may be less than the energy of the second and fourth LDD sub-implants (4028, 3032). In yet another embodiment, a dose of the first LDD sub-implant (4026) may be substantially equal to a dose of the third LDD sub-implant (4030), and a dose of the second LDD sub-implant (4028) may be substantially equal to a dose of the fourth LDD sub-implant (4032), while the dose of the first and third LDD sub-implants (4026, 3030) may be less than the dose of the second and fourth LDD sub-implants (4028, 3032).

Similarly, the S/D ion implant process includes a first S/D sub-implant (4034) angled toward the upper direction, a second S/D sub-implant (4036) angled toward the right direction, a third S/D sub-implant (4038) angled toward the lower direction, and a fourth S/D sub-implant (4040) angled toward the left direction. A tilt angle of the first halo sub-implant (4034) from an axis perpendicular to the top surface of the integrated circuit (4000) is substantially equal to a tilt angle of the third S/D sub-implant (4038), and a tilt angle of the second S/D sub-implant (4036) is substantially equal to a tilt angle of the fourth S/D sub-implant (4040). The tilt angle of the first and third S/D sub-implants (4034, 3038) are greater than the tilt angle of the second and fourth S/D sub-implants (4036, 3040). In a further embodiment, an energy of the first S/D sub-implant (4034) may be substantially equal to an energy of the third S/D sub-implant (4038), and an energy of the second S/D sub-implant (4036) may be substantially equal to an energy of the fourth S/D sub-implant (4040), while the energy of the first and third S/D sub-implants (4034, 3038) may be greater than the energy of the second and fourth S/D sub-implants (4036, 3040). In yet another embodiment, a dose of the first S/D sub-implant (4034) may be substantially equal to a dose of the third S/D sub-implant (4038), and a dose of the second S/D sub-implant (4036) may be substantially equal to a dose of the fourth S/D sub-implant (4040), while the dose of the first and third S/D sub-implants (4034, 3038) may be greater than the dose of the second and fourth S/D sub-implants (4036, 3040).

FIG. 4B and FIG. 4C are cross-sections of the integrated circuit (4000), through the first transistor (4010) and the second transistor (4012) depicted in FIG. 4A. FIG. 4B depicts a cross-section at section line A-A of FIG. 4A. FIG. 4C depicts a cross-section at section line B-B of FIG. 4A. Referring to FIG. 4B, the first transistor (4010) is formed on a substrate (4042) of the integrated circuit (4000), as described in reference to FIG. 1A. Elements of field oxide (4044) may be formed at a top surface of the substrate (4042), as described in reference to FIG. 1B. A first well (4046) may be formed in the substrate (4042), as described in reference to FIG. 1B. The first transistor (4010) includes a first gate dielectric layer (4048), formed on a top surface of the substrate (4042) as described in reference to FIG. 1B. A first gate (4014) is formed on a top surface of the first gate dielectric layer (4048), as described in reference to FIG. 1B.

A first drain side LDD implanted region (4052) and a first source side LDD implanted region (4054) are formed by the first LDD sub-implant, not shown in FIG. 4B for clarity, the second LDD sub-implant (4028), the third LDD sub-implant, not shown in FIG. 4B for clarity, and the fourth LDD sub-implant (4032). Spatial distributions of LDD dopants in the first drain side LDD implanted region (4052) and the first source side LDD implanted region (4054) are established by the angles, doses and energies of the LDD sub-implants. Because the first and third LDD sub-implants are symmetric with respect to the upper-lower longitudinal axis of the first gate (4014), and because the second LDD sub-implant (4028) and the fourth LDD sub-implant (4032) have substantially equal angles, doses and energies, the first drain side LDD implanted region (4052) and the first source side LDD implanted region (4054) are substantially symmetric with respect to the first gate (4014). A drain side lateral overlap of the first drain side LDD implanted region (4052) with the first gate (4014) is substantially equal to a source side lateral overlap of the first source side LDD implanted region (4054) with the first gate (4014).

A first gate sidewall spacer (4054) is formed on lateral surfaces of the first gate (4014), as described in reference to FIG. 1B. A first drain side S/D implanted region (4056) and a first source side S/D implanted region (4058) are formed by the first S/D sub-implant, not shown in FIG. 4B for clarity, the second S/D sub-implant (4036), the third S/D sub-implant, not shown in FIG. 4B for clarity, and the fourth S/D sub-implant (4040). Spatial distributions of S/D dopants in the first drain side S/D implanted region (4056) and the first source side S/D implanted region (4058) are established by the angles, doses and energies of the S/D sub-implants. Because the first and third S/D sub-implants are symmetric with respect to the upper-lower longitudinal axis of the first gate (4014), and because the second S/D sub-implant (4036) and the fourth S/D sub-implant (4040) have substantially equal angles, doses and energies, the first drain side S/D implanted region (4056) and the first source side S/D implanted region (4058) are substantially symmetric with respect to the first gate (4014). A drain side lateral overlap of the first drain side S/D implanted region (4056) with the first gate sidewall spacer (4054) is substantially equal to a source side lateral overlap of the first source side S/D implanted region (4058) with the first gate sidewall spacer (4054).

Referring to FIG. 4C, the second transistor (4012) is formed on the substrate (4042) of the integrated circuit (4000), as described in reference to FIG. 1B. Elements of field oxide (4044) may be formed at a top surface of the substrate (4042), as described in reference to FIG. 1B. A second well (4062) may be formed in the substrate (4042) in a channel region of the second transistor (4012). A third well (4064) may be formed in the substrate (4042) in a drain region of the second transistor (4012). The second transistor (4012) includes a second gate dielectric layer (4066), formed on a top surface of the substrate (4042) as described in reference to FIG. 1B. A second gate (4016) is formed on a top surface of the second gate dielectric layer (4066), as described in reference to FIG. 1B.

A second source side LDD implanted region (4068) and possibly an optional second drain side LDD implanted region, not shown in FIG. 4C, are formed by the first LDD sub-implant (4026), the second LDD sub-implant, not shown in FIG. 4C for clarity, the third LDD sub-implant (4030), and the fourth LDD sub-implant, not shown in FIG. 4C for clarity. In some embodiments, such as DMOS transistors, the LDD sub-implants may be blocked from the drain side of the second transistor (4012), as depicted in FIG. 4C. Spatial distributions of LDD dopants in the second source side LDD implanted region (4068) and the optional second drain side LDD implanted region, if formed, are established by the angles, doses and energies of the LDD sub-implants.

A second gate sidewall spacer (4070) is formed on lateral surfaces of the second gate (4016), as described in reference to FIG. 1B. A second source side S/D implanted region (4072) and a second drain side S/D implanted region (4074) are formed by the first S/D sub-implant (4034), the second S/D sub-implant, the third S/D sub-implant (4038) and the fourth S/D sub-implant. Spatial distributions of S/D dopants in the A second source side S/D implanted region (4072) and the second drain side S/D implanted region (4074) are established by the angles, doses and energies of the S/D sub-implants. Because the second and fourth S/D sub-implants are symmetric with respect to the left-right longitudinal axis of the second gate (4016), and because the first S/D sub-implant (4034) and the third S/D sub-implant (4038) have substantially equal angles, doses and energies, the second drain side S/D implanted region (4074) and the second source side S/D implanted region (4072) are substantially symmetric with respect to the second gate (4016). A drain side lateral overlap of the second drain side S/D implanted region (4074) with the second gate sidewall spacer (4070) is substantially equal to a source side lateral overlap of the second source side S/D implanted region (4072) with the second gate sidewall spacer (4070).

Referring to FIG. 4A through FIG. 4C collectively, in the instant embodiment, the tilt angles of the first and third LDD sub-implants (4026, 4030) are less than the tilt angles of the second and fourth LDD sub-implants (4028, 4032), providing a smaller lateral overlap between the second gate (4016) and the second source side LDD implanted regions (4068) than between the first gate (4014) and first drain and source side LDD implanted regions (4052, 4054). Furthermore, in the instant embodiment, the tilt angles of the first and third S/D sub-implants (4034, 4038) are less than the tilt angles of the second and fourth S/D sub-implants (4036, 4040), providing smaller lateral overlaps between the second gate sidewall spacer (4070) and the second source side and drain side S/D implanted regions (4072, 4074) than between the first gate sidewall spacer (4054) and the first drain and source side S/D implanted regions (4058, 4060). The second transistor (4012) may benefit from smaller lateral overlaps of source side LDD and S/D implanted regions, by providing desired balances between on-state current densities and off-state leakage current densities. Providing smaller source side LDD and S/D overlaps in the second transistor (4012) concurrently with providing relatively larger LDD and S/D overlaps in a first transistor (4010) in the integrated circuit (4000) may advantageously reduce fabrication cost and fabrication complexity of the integrated circuit (4000).

It will be recognized by those familiar with integrated circuit fabrication that the advantages of the embodiment discussed in reference to FIG. 4A through FIG. 4C may be realized by similar embodiments in which relative positions of drain and source areas are exchanged, with appropriate changes to angled sub-implants.

It will be recognized by those familiar with integrated circuit fabrication that the advantages of the embodiment discussed in reference to FIG. 4A through FIG. 4C may be realized by similar embodiments in which relative orientations of the first transistor (4010) and the second transistor (4012) are exchanged, with appropriate changes to angled sub-implants.

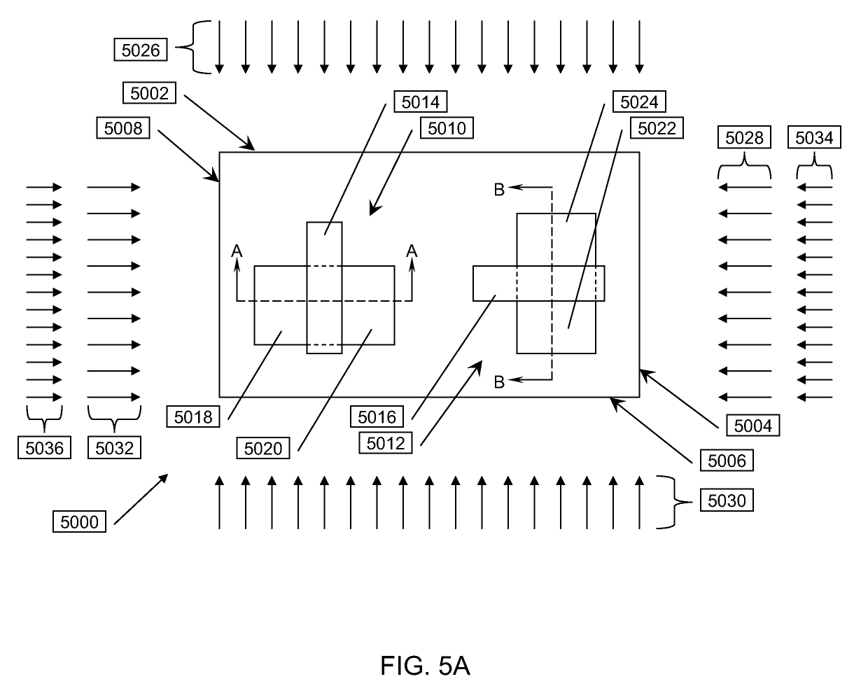

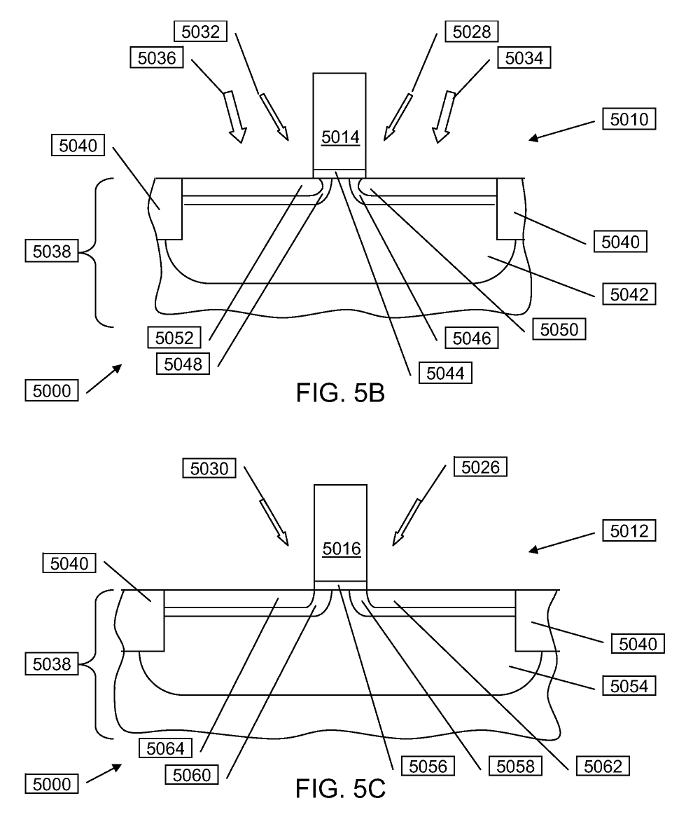

FIG. 5A through FIG. 5C depict an integrated circuit containing a first transistor and a second transistor formed according to a third specific embodiment of the instant invention. FIG. 5A is a top view of the integrated circuit (5000) with an upper edge (5002), a right edge (5004), a lower edge (5006) and a left edge (5008). The integrated circuit contains a first transistor (5010) and a second transistor (5012). The first transistor (5010) has a first gate (5014) with an upper-lower longitudinal axis. The second transistor (5012) has a second gate (5016) with a left-right longitudinal axis. The first transistor (5010) includes a first source area (5018) adjacent to, and on a left side of, the first gate (5014), and a first drain area (5020) adjacent to the first gate (5014) opposite the first source area (5018). The second transistor (5012) includes a second source area (5022) adjacent to, and on a lower side of, the second gate (5016), and a second drain area (5024) adjacent to the second gate (5016) opposite the second source area (5022). Other components in the integrated circuit (5000) are not shown in FIG. 5A for clarity.

The first transistor (5010) and the second transistor (5012) are formed using halo and LDD ion implant processes which include angled sub-implants to produce halo and LDD ion implanted layers at a top surface of the integrated circuit (5000). The halo ion implant process includes a first halo sub-implant (5026) angled toward the upper direction, a second halo sub-implant (5028) angled toward the right direction, a third halo sub-implant (5030) angled toward the lower direction, and a fourth halo sub-implant (5032) angled toward the left direction. Tilt angles of the halo sub-implants (5026, 5028, 5030, 5032) from an axis perpendicular to the top surface of the integrated circuit (5000) are substantially equal in the instant embodiment. Furthermore, doses and energies of the halo sub-implants (5026, 5028, 5030, 5032) are substantially equal in the instant embodiment.

The LDD ion implant process includes a first LDD sub-implant (5034) angled toward the right direction, and a second LDD sub-implant (5036) angled toward the left direction. No LDD sub-implants angled toward the upper or lower directions are performed in the instant embodiment. Tilt angles of the first and second LDD sub-implants (5034, 5036) from the perpendicular axis are substantially equal in the instant embodiment. Furthermore, doses and energies of the LDD sub-implants (5034, 5036) are substantially equal in the instant embodiment.

FIG. 5B and FIG. 5C are cross-sections of the integrated circuit (5000), through the first transistor (5010) and the second transistor (5012) depicted in FIG. 5A. FIG. 5B depicts a cross-section at section line A-A of FIG. 5A. FIG. 5C depicts a cross-section at section line B-B of FIG. 5A. Referring to FIG. 5B, the first transistor (5010) is formed on a substrate (5038) of the integrated circuit (5000), as described in reference to FIG. 1B. Elements of field oxide (5040) may be formed at a top surface of the substrate (5042), as described in reference to FIG. 1B. A first well (5042) may be formed in the substrate (5038), as described in reference to FIG. 1B. The first transistor (5010) includes a first gate dielectric layer (5044), formed on a top surface of the substrate (5038) as described in reference to FIG. 1B. The first gate (5014) is formed on a top surface of the first gate dielectric layer (5044), as described in reference to FIG. 1B.

A first drain side halo implanted region (5046) and a first source side halo implanted region (5048) are formed by the first halo sub-implant, not shown in FIG. 5B for clarity, the second halo sub-implant (5028), the third halo sub-implant, not shown in FIG. 5B for clarity, and the fourth halo sub-implant (5032). Spatial distributions of halo dopants in the first drain side halo implanted region (5046) and the first source side halo implanted region (5048) are established by the angles, doses and energies of the halo sub-implants. Because the first and third halo sub-implants are symmetric with respect to the upper-lower longitudinal axis of the first gate (5014), and because the second halo sub-implant (5028) and the fourth halo sub-implant (5032) have substantially equal angles, doses and energies, the first drain side halo implanted region (5046) and the first source side halo implanted region (5048) are substantially symmetric with respect to the first gate (5014). A drain side lateral overlap of the first drain side halo implanted region (5046) with the first gate (5014) is substantially equal to a source side lateral overlap of the first source side halo implanted region (5048) with the first gate (5014).

A first drain side LDD implanted region (5050) and a first source side LDD implanted region (5052) are formed by the first LDD sub-implant (5034) and the second LDD sub-implant (5036). Spatial distributions of LDD dopants in the first drain side LDD implanted region (5050) and the first source side LDD implanted region (5052) are established by the angles, doses and energies of the LDD sub-implants. Because the first and second LDD sub-implants (5034, 5036) are symmetric with respect to the upper-lower longitudinal axis of the first gate (5014), the first drain side LDD implanted region (5050) and the first source side LDD implanted region (5052) are substantially symmetric with respect to the first gate (5014). A drain side lateral overlap of the first drain side LDD implanted region (5050) with the first gate (5014) is substantially equal to a source side lateral overlap of the first source side LDD implanted region (5052) with the first gate (5014). Because the first LDD sub-implant (5034) and the second LDD sub-implant (5036) are tilted from the perpendicular axis, and because no LDD sub-implants angled toward the upper or lower directions were performed in the instant embodiment, lateral edges of the first drain side LDD implanted region (5050) and the first source side LDD implanted region (5052) adjacent to the first gate (5014) may exhibit retrograde profiles. Retrograde profiles of LDD implanted regions may advantageously reduce certain degradation mechanisms of the first transistor (5010) such as channel hot carrier degradation or negative bias temperature instability.

Referring to FIG. 5C, the second transistor (5012) is formed on the substrate (5038) of the integrated circuit (5000), as described in reference to FIG. 1B. Elements of field oxide (5040) may be formed at a top surface of the substrate (5038), as described in reference to FIG. 1B. A second well (5054) may be formed in the substrate (5038), as described in reference to FIG. 1B. The second transistor (5012) includes a second gate dielectric layer (5056), formed on a top surface of the substrate (5038) as described in reference to FIG. 1B. The second gate (5016) is formed on a top surface of the second gate dielectric layer (5056), as described in reference to FIG. 1B.

A second drain side halo implanted region (5058) and a second source side halo implanted region (5060) are formed by the first halo sub-implant (5026), the second halo sub-implant, not shown in FIG. 5C for clarity, the third halo sub-implant (5030), and the fourth halo sub-implant, not shown in FIG. 5C for clarity. Spatial distributions of halo dopants in the second drain side halo implanted region (5058) and the second source side halo implanted region (5060) are established by the angles, doses and energies of the halo sub-implants. Because the second and fourth halo sub-implants are symmetric with respect to the left-right longitudinal axis of the second gate (5016), and because the first halo sub-implant (5026) and the third halo sub-implant (5030) have substantially equal angles, doses and energies, the second drain side halo implanted region (5058) and the second source side halo implanted region (5060) are substantially symmetric with respect to the second gate (5016). A drain side lateral overlap of the second drain side halo implanted region (5058) with the second gate (5016) is substantially equal to a source side lateral overlap of the second source side halo implanted region (5060) with the second gate (5016).

A second drain side LDD implanted region (5062) and a second source side LDD implanted region (5064) are formed by the first LDD sub-implant, not shown in FIG. 5C for clarity, and the second LDD sub-implant, also not shown in FIG. 5C for clarity. Spatial distributions of LDD dopants in the second drain side LDD implanted region (5062) and the second source side LDD implanted region (5064) are established by the angles, doses and energies of the LDD sub-implants. Because the first and second LDD sub-implants are symmetric with respect to the left-right longitudinal axis of the second gate (5016), the second drain side LDD implanted region (5062) and the second source side LDD implanted region (5064) are substantially symmetric with respect to the second gate (5016). Because the tilt angles of the first and second LDD sub-implants are oriented parallel to the left-right longitudinal axis of the second gate (5016), substantially no lateral overlap is produced between the second gate (5016) and the second drain side LDD implanted region (5062) and the second source side LDD implanted region (5064), which may advantageously reduce an off-state leakage current in the second transistor (5012).

It will be recognized by those familiar with integrated circuit fabrication that the advantages of the embodiment discussed in reference to FIG. 5A through FIG. 5C may be realized by similar embodiments in which relative positions of drain and source areas are exchanged, with appropriate changes to angled sub-implants.

It will be recognized by those familiar with integrated circuit fabrication that the advantages of the embodiment discussed in reference to FIG. 5A through FIG. 5C may be realized by similar embodiments in which relative orientations of the first transistor (5010) and the second transistor (5012) are exchanged, with appropriate changes to angled sub-implants.

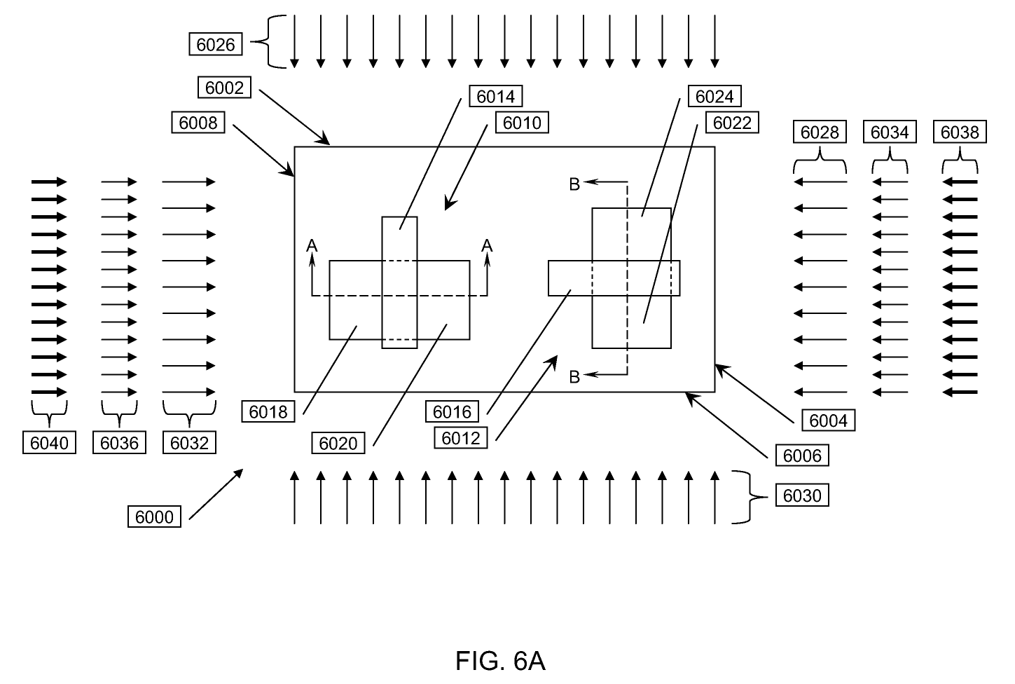

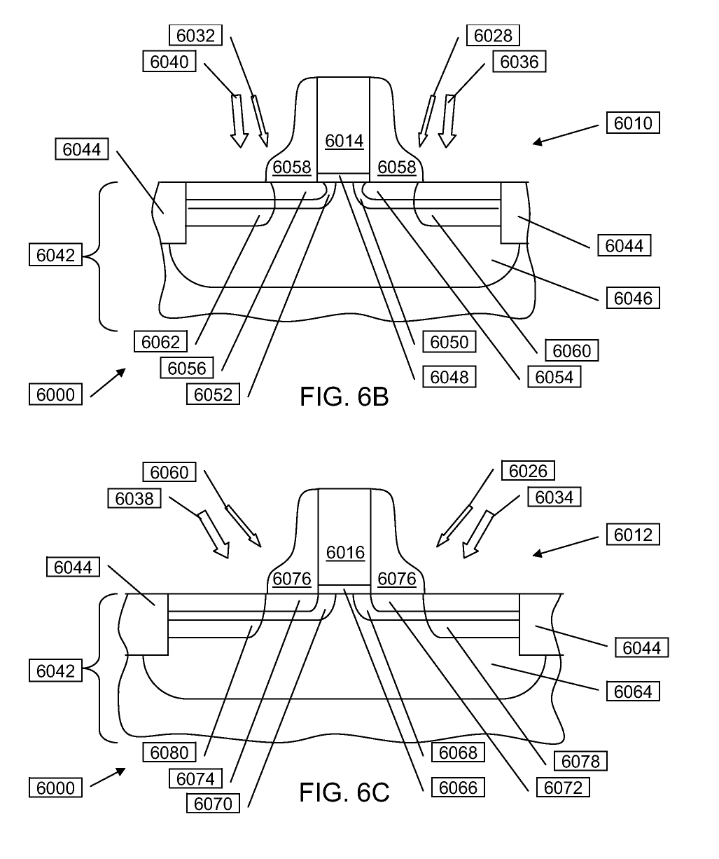

FIG. 6A through FIG. 6C depict an integrated circuit containing a first transistor and a second transistor formed according to a fourth specific embodiment of the instant invention. FIG. 6A is a top view of the integrated circuit (6000) with an upper edge (6002), a right edge (6004), a lower edge (6006) and a left edge (6008). The integrated circuit contains a first transistor (6010) and a second transistor (6012). The first transistor (6010) has a first gate (6014) with an upper-lower longitudinal axis. The second transistor (6012) has a second gate (6016) with a left-right longitudinal axis. The first transistor (6010) includes a first source area (6018) adjacent to, and on a left side of, the first gate (6014), and a first drain area (6020) adjacent to the first gate (6014) opposite the first source area (6018). The second transistor (6012) includes a second source area (6022) adjacent to, and on a lower side of, the second gate (6016), and a second drain area (6024) adjacent to the second gate (6016) opposite the second source area (6022). Other components in the integrated circuit (6000) are not shown in FIG. 6A for clarity.

The first transistor (6010) and the second transistor (6012) are formed using halo, LDD and S/D ion implant processes which include angled sub-implants to produce halo, LDD and S/D ion implanted layers at a top surface of the integrated circuit (6000). The halo ion implant process includes a first halo sub-implant (6026) angled toward the upper direction, a second halo sub-implant (6028) angled toward the right direction, a third halo sub-implant (6030) angled toward the lower direction, and a fourth halo sub-implant (6032) angled toward the left direction. Tilt angles of the halo sub-implants (6026, 6028, 6030, 6032) from an axis perpendicular to the top surface of the integrated circuit (6000) are substantially equal in the instant embodiment. Furthermore, doses and energies of the halo sub-implants (6026, 6028, 6030, 6032) are substantially equal in the instant embodiment.

The LDD ion implant process includes a first LDD sub-implant (6034) angled toward the right direction, and a second LDD sub-implant (6036) angled toward the left direction. No LDD sub-implants angled toward the upper or lower directions are performed in the instant embodiment. Tilt angles of the first and second LDD sub-implants (6034, 6036) from the perpendicular axis are substantially equal in the instant embodiment. Furthermore, doses and energies of the LDD sub-implants (6034, 6036) are substantially equal in the instant embodiment.

The S/D ion implant process includes a first S/D sub-implant (6038) angled toward the right direction, and a second S/D sub-implant (6040) angled toward the left direction. No S/D sub-implants angled toward the upper or lower directions are performed in the instant embodiment. Tilt angles of the first and second S/D sub-implants (6038, 6040) from the perpendicular axis are substantially equal in the instant embodiment. Furthermore, doses and energies of the S/D sub-implants (6038, 6040) are substantially equal in the instant embodiment.

FIG. 6B and FIG. 6C are cross-sections of the integrated circuit (6000), through the first transistor (6010) and the second transistor (6012) depicted in FIG. 6A. FIG. 6B depicts a cross-section at section line A-A of FIG. 6A. FIG. 6C depicts a cross-section at section line B-B of FIG. 6A. Referring to FIG. 6B, the first transistor (6010) is formed on a substrate (6042) of the integrated circuit (6000), as described in reference to FIG. 1B. Elements of field oxide (6044) may be formed at a top surface of the substrate (6042), as described in reference to FIG. 1B. A first well (6046) may be formed in the substrate (6042), as described in reference to FIG. 1B. The first transistor (6010) includes a first gate dielectric layer (6048), formed on a top surface of the substrate (6042) as described in reference to FIG. 1B. The first gate (6014) is formed on a top surface of the first gate dielectric layer (6048), as described in reference to FIG. 1B.

A first drain side halo implanted region (6050) and a first source side halo implanted region (6052) are formed by the first halo sub-implant, not shown in FIG. 6B for clarity, the second halo sub-implant (6028), the third halo sub-implant, not shown in FIG. 6B for clarity, and the fourth halo sub-implant (6032). Spatial distributions of halo dopants in the first drain side halo implanted region (6050) and the first source side halo implanted region (6052) are established by the angles, doses and energies of the halo sub-implants. Because the first and third halo sub-implants are symmetric with respect to the upper-lower longitudinal axis of the first gate (6014), and because the second halo sub-implant (6028) and the fourth halo sub-implant (6032) have substantially equal angles, doses and energies, the first drain side halo implanted region (6050) and the first source side halo implanted region (6052) are substantially symmetric with respect to the first gate (6014). A drain side lateral overlap of the first drain side halo implanted region (6050) with the first gate (6014) is substantially equal to a source side lateral overlap of the first source side halo implanted region (6052) with the first gate (6014).

A first drain side LDD implanted region (6054) and a first source side LDD implanted region (6056) are formed by the first LDD sub-implant (6034) and the second LDD sub-implant (6036). Spatial distributions of LDD dopants in the first drain side LDD implanted region (6054) and the first source side LDD implanted region (6056) are established by the angles, doses and energies of the LDD sub-implants. Because the first and second LDD sub-implants (6034, 6036) are symmetric with respect to the upper-lower longitudinal axis of the first gate (6014), the first drain side LDD implanted region (6054) and the first source side LDD implanted region (6056) are substantially symmetric with respect to the first gate (6014). A drain side lateral overlap of the first drain side LDD implanted region (6054) with the first gate (6014) is substantially equal to a source side lateral overlap of the first source side LDD implanted region (6056) with the first gate (6014). Because the first LDD sub-implant (6034) and the second LDD sub-implant (6036) are tilted from the perpendicular axis, and because no LDD sub-implants angled toward the upper or lower directions were performed in the instant embodiment, lateral edges of the first drain side LDD implanted region (6054) and the first source side LDD implanted region (6056) adjacent to the first gate (6014) may exhibit retrograde profiles. Retrograde profiles of LDD implanted regions may advantageously reduce certain degradation mechanisms of the first transistor (6010) such as channel hot carrier degradation or negative bias temperature instability.

A first gate sidewall spacer (6058) is formed on lateral surfaces of the first gate (6014), as described in reference to FIG. 1B. A first drain side S/D implanted region (6060) and a first source side S/D implanted region (6062) are formed by the first S/D sub-implant (6038) and the second S/D sub-implant (6040). Spatial distributions of S/D dopants in the first drain side S/D implanted region (6060) and the first source side S/D implanted region (6062) are established by the angles, doses and energies of the S/D sub-implants. Because the first and second S/D sub-implants (6038, 6040) are symmetric with respect to the upper-lower longitudinal axis of the first gate (6014), the first drain side S/D implanted region (6060) and the first source side S/D implanted region (6062) are substantially symmetric with respect to the first gate (6014). A drain side lateral overlap of the first drain side S/D implanted region (6060) with the first gate sidewall spacer (6058) is substantially equal to a source side lateral overlap of the first source side S/D implanted region (6062) with the first gate sidewall spacer (6058). Because the first S/D sub-implant (6034) and the second S/D sub-implant (6036) are tilted from the perpendicular axis, and because no S/D sub-implants angled toward the upper or lower directions were performed in the instant embodiment, lateral edges of the first drain side S/D implanted region (6060) and the first source side S/D implanted region (6062) adjacent to the first gate sidewall spacer (6058) may exhibit retrograde profiles. Retrograde profiles of S/D implanted regions may advantageously further reduce certain degradation mechanisms of the first transistor (6010) such as channel hot carrier degradation or negative bias temperature instability.

Referring to FIG. 6C, the second transistor (6012) is formed on the substrate (6042) of the integrated circuit (6000), as described in reference to FIG. 1B. Elements of field oxide (6044) may be formed at a top surface of the substrate (6042), as described in reference to FIG. 1B. A second well (6064) may be formed in the substrate (6042), as described in reference to FIG. 1B. The second transistor (6012) includes a second gate dielectric layer (6066), formed on a top surface of the substrate (6042) as described in reference to FIG. 1B. The second gate (6016) is formed on a top surface of the second gate dielectric layer (6066), as described in reference to FIG. 1B.

A second drain side halo implanted region (6068) and a second source side halo implanted region (6070) are formed by the first halo sub-implant (6026), the second halo sub-implant, not shown in FIG. 6C for clarity, the third halo sub-implant (6030), and the fourth halo sub-implant, not shown in FIG. 6C for clarity. Spatial distributions of halo dopants in the second drain side halo implanted region (6068) and the second source side halo implanted region (6070) are established by the angles, doses and energies of the halo sub-implants. Because the second and fourth halo sub-implants are symmetric with respect to the left-right longitudinal axis of the second gate (6016), and because the first halo sub-implant (6026) and the third halo sub-implant (6030) have substantially equal angles, doses and energies, the second drain side halo implanted region (6068) and the second source side halo implanted region (6070) are substantially symmetric with respect to the second gate (6016). A drain side lateral overlap of the second drain side halo implanted region (6068) with the second gate (6016) is substantially equal to a source side lateral overlap of the second source side halo implanted region (6070) with the second gate (6016).

A second drain side LDD implanted region (6072) and a second source side LDD implanted region (6074) are formed by the first LDD sub-implant, not shown in FIG. 6C for clarity, and the second LDD sub-implant, also not shown in FIG. 6C for clarity. Spatial distributions of LDD dopants in the second drain side LDD implanted region (6072) and the second source side LDD implanted region (6074) are established by the angles, doses and energies of the LDD sub-implants. Because the first and second LDD sub-implants are symmetric with respect to the left-right longitudinal axis of the second gate (6016), the second drain side LDD implanted region (6072) and the second source side LDD implanted region (6074) are substantially symmetric with respect to the second gate (6016). Because the tilt angles of the first and second LDD sub-implants are oriented parallel to the left-right longitudinal axis of the second gate (6016), substantially no lateral overlap is produced between the second gate (6016) and the second drain side LDD implanted region (6072) and the second source side LDD implanted region (6074), which may advantageously reduce an off-state leakage current in the second transistor (6012).

A second gate sidewall spacer (6076) is formed on lateral surfaces of the second gate (6016), as described in reference to FIG. 1B. A second drain side S/D implanted region (6078) and a second source side S/D implanted region (6080) are formed by the first S/D sub-implant, not shown in FIG. 6C for clarity, and the second S/D sub-implant, also not shown in FIG. 6C for clarity. Spatial distributions of S/D dopants in the second drain side S/D implanted region (6078) and the second source side S/D implanted region (6080) are established by the angles, doses and energies of the S/D sub-implants. Because the first and second S/D sub-implants are symmetric with respect to the left-right longitudinal axis of the second gate (6016), the second drain side S/D implanted region (6078) and the second source side S/D implanted region (6080) are substantially symmetric with respect to the second gate (6016). Because the tilt angles of the first and second S/D sub-implants are oriented parallel to the left-right longitudinal axis of the second gate (6016), substantially no lateral overlap is produced between the second gate (6016) and the second drain side S/D implanted region (6078) and the second source side S/D implanted region (6080), which may advantageously further reduce an off-state leakage current in the second transistor (6012).

It will be recognized by those familiar with integrated circuit fabrication that the advantages of the embodiment discussed in reference to FIG. 6A through FIG. 6C may be realized by similar embodiments in which relative positions of drain and source areas are exchanged, with appropriate changes to angled sub-implants.

It will be recognized by those familiar with integrated circuit fabrication that the advantages of the embodiment discussed in reference to FIG. 6A through FIG. 6C may be realized by similar embodiments in which relative orientations of the first transistor (6010) and the second transistor (6012) are exchanged, with appropriate changes to angled sub-implants.

What is claimed is:

1. An integrated circuit, comprising:
a first MOS transistor formed at said top surface of said integrated circuit, said first MOS transistor further including:
a first MOS gate, said first MOS gate having a first longitudinal axis;
a first drain area, said first drain area being located adjacent to said first MOS gate;
a first source area, said first source area being located adjacent to said first MOS gate opposite from said first drain area;
a first drain side implanted region located in said first drain area, wherein said first drain side implanted region has a first drain side lateral overlap with said first MOS gate; and
a first source side implanted region located in said first source area, wherein said first source side implanted region has a first source side lateral overlap with said first MOS gate; and
a second MOS transistor formed at said top surface of said integrated circuit, said second MOS transistor further including:
a second MOS gate, said second MOS gate having a second longitudinal axis perpendicular to said first longitudinal axis;
a second drain area, said second drain area being located adjacent to said second MOS gate;
a second source area, said second source area being located adjacent to said second MOS gate opposite from said second drain area;
a second drain side implanted region located in said second drain area, wherein said second drain side implanted region has a second drain side lateral overlap with said second MOS gate, such that said second drain side lateral overlap is different from said first drain side lateral overlap.

2. The integrated circuit of claim 1, further comprising a second source side implanted region located in said second source area, wherein said second source side implanted region has a second source side lateral overlap with said second MOS gate, such that said second source side lateral overlap is different from said first source side lateral overlap.

3. The integrated circuit of claim 2, in which:
said first drain side implanted region and said first source side implanted region are substantially symmetric with respect to said first MOS gate; and
said second drain side implanted region and said second source side implanted region are substantially symmetric with respect to said second MOS gate.

4. The integrated circuit of claim 2, in which said first source side implanted region, first drain side implanted region, second source side implanted regions and second drain side implanted region are halo regions.

5. The integrated circuit of claim 2, in which said first source side implanted region, first drain side implanted region, second source side implanted regions and second drain side implanted region are LDD regions.

6. The integrated circuit of claim 2, further including:
a third source side implanted region located in said first source area, wherein said third source side implanted region has a third source side lateral overlap with said first MOS gate;
a third drain side implanted region located in said first drain area, wherein said third drain side implanted region has a third drain side lateral overlap with said first MOS gate;
a fourth source side implanted region located in said second source area, wherein said fourth source side implanted region has a fourth source side lateral overlap with said second MOS gate, such that said fourth source side lateral overlap is different from said third source side lateral overlap; and
a fourth drain side implanted region located in said second drain area, wherein said fourth drain side implanted region has a fourth drain side lateral overlap with said second MOS gate, such that said fourth drain side lateral overlap is different from said third drain side lateral overlap.

7. The integrated circuit of claim 6, further including:
a first gate sidewall spacer formed on lateral surfaces of said first MOS gate;
a second gate sidewall spacer formed on lateral surfaces of said second MOS gate;
a fifth source side implanted region located in said first source area, wherein said fifth source side implanted region has a fifth source side lateral overlap with said first gate sidewall spacer;
a fifth drain side implanted region located in said first drain area, wherein said fifth drain side implanted region has a fifth drain side lateral overlap with said first gate sidewall spacer;
a sixth source side implanted region located in said second source area, wherein said sixth source side implanted region has a sixth source side lateral overlap with said second gate sidewall spacer, such that said sixth source side lateral overlap is different than said fifth source side lateral overlap; and
a sixth drain side implanted region located in said second drain area, wherein said sixth drain side implanted region has a sixth drain side lateral overlap with said second gate sidewall spacer, such that said sixth drain side lateral overlap is different from said fifth source side lateral overlap.

8. A process of forming an integrated circuit, comprising the steps of:
forming a layer of field oxide in a top region of said top surface of said integrated circuit, such that a first transistor area and a second transistor area are defined at said top surface by being free of said field oxide;
forming a first gate dielectric layer on a top surface of said integrated circuit in said first transistor area;
forming a second gate dielectric layer on a top surface of said integrated circuit in said second transistor area;
forming a first MOS gate on said first gate dielectric layer, such that said first MOS gate has a first longitudinal axis, and such that said first transistor area includes a first source area adjacent to said first MOS gate and a first drain area adjacent to said first MOS gate opposite said first source area;
forming a second MOS gate on said second gate dielectric layer, such that said second MOS gate has a second longitudinal axis perpendicular to said first longitudinal axis, and such that said second transistor area includes a second source area adjacent to said second MOS gate and a second drain area adjacent to said second MOS gate opposite said second source area; and
performing a first ion implant process including the step of performing a first angled sub-implant, wherein said first angled sub-implant is tilted from an axis perpendicular to said top surface in a first direction, such that:
a first source side implanted region is formed in said first source area, wherein said first source side implanted region has a first source side lateral overlap with said first MOS gate;
a first drain side implanted region is formed in said first drain area; wherein said first drain side implanted region has a first drain side lateral overlap with said first MOS gate, such that said first drain side lateral overlap is substantially equal to said first source side lateral overlap; and
a second drain side implanted region is formed in said second drain area, wherein said second drain side implanted region has a second drain side lateral overlap with said second MOS gate, such that said second drain side lateral overlap is different than said first drain side lateral overlap.

9. The process of claim 8, wherein said performing a first ion implant process further forms a second source side implanted region in said second source area, wherein said second source side implanted region has a second source side lateral overlap with said second MOS gate that is different than said first source side lateral overlap;

10. The process of claim 9, wherein said step of performing a first ion implant process further comprises the step of performing a second angled sub-implant tilted from said perpendicular axis in a second direction distinct from said first direction, such that at least one of a tilt angle, a dose and an energy of said second angled sub-implant is different from a tilt angle, a dose and an energy of said first angled sub-implant.

11. The process of claim 9, in which said first ion implant process is a halo implant process.

12. The process of claim 8, in which said first ion implant process is an LDD implant process.

13. The process of claim 10, further comprising the step of performing a second ion implant process including the steps of:
performing a first angled LDD sub-implant tilted from an axis perpendicular to said top surface in said first direction; and
performing a second angled LDD sub-implant tilted from said perpendicular axis in said second direction, such that:
a first source side LDD region is formed in said first source area, wherein said first source side LDD region has a first source side LDD lateral overlap with said first MOS gate;
a first drain side LDD region is formed in said first drain area, wherein said first drain side LDD region has a first drain side LDD lateral overlap with said first MOS gate;
a second source side LDD region is formed in said second source area, wherein said second source side LDD region has a second source side LDD lateral overlap with said second MOS gate, such that said second source side LDD lateral overlap is different than said first source side lateral LDD overlap; and
a second drain side LDD region is formed in said second drain area, wherein said second drain side LDD region has a second drain side LDD lateral overlap with said second MOS gate, such that said second drain side LDD lateral overlap is different than said first drain side LDD lateral overlap.

14. The process of claim 13, further including the steps of:
forming a first gate sidewall spacer on lateral surfaces of said first MOS gate;
forming a second gate sidewall spacer on lateral surfaces of said second MOS gate;
performing a third ion implant process by:
performing a first angled S/D sub-implant tilted from an axis perpendicular to said top surface in the first direction; and
performing a second angled S/D sub-implant tilted from said perpendicular axis in the second direction, such that:
a first source side S/D region is formed in said first source area, wherein said first source side S/D region has a first source side S/D lateral overlap with said first gate sidewall spacer;
a first drain side S/D region is formed in said first drain area, wherein said first drain side S/D region has a first drain side lateral overlap with said first gate sidewall spacer;
a second source side S/D region is formed in said second source area, wherein said second source side S/D region has a second source side S/D lateral overlap with said second gate sidewall spacer, such that said second source side S/D lateral overlap is different than said first source side S/D lateral overlap; and
a second drain side S/D region is formed in said second drain area, wherein said second drain side S/D region has a second drain side S/D lateral overlap with said second gate sidewall spacer, such that said second drain side S/D lateral overlap is different than said first drain side S/D lateral overlap.

15. The process of claim 10, wherein said second direction is opposite said first direction.

16. The process of claim 10 wherein said second direction is perpendicular to said first direction.

17. The process of claim 10, wherein said second direction is angled 450 from said first direction.

18. The process of claim 10, wherein said step of performing a first ion implant process further comprises the step of performing a third angled sub-implant tilted from said perpendicular axis in a third direction opposite from said first direction, such that a tilt angle, a dose and an energy of said third angled sub-implant is equal to the tilt angle, dose and energy of said first angled sub-implant.

19. The process of claim 18, wherein said step of performing a first ion implant process further comprises the step of performing a fourth angled sub-implant tilted from said perpendicular axis in a fourth direction opposite said second direction, such that a tilt angle, a dose and an energy of said fourth angled sub-implant is equal to the tilt angle, dose and energy of said second angled sub-implant.

20. The process of claim 18, wherein said step of performing a first ion implant process further comprises the step of performing a fourth angled sub-implant tilted from said perpendicular axis in a fourth direction opposite said second direction, such that a tilt angle, a dose and an energy of said fourth angled sub-implant is different from the tilt angle, dose and energy of said second angled sub-implant.
